(19) United States
(12) Patent Application Publication
(10) Pub. No.: US 2026/0334276 A1
(43) Pub. Date: Oct. 22, 2026

(54) SEMICONDUCTOR PACKAGE INCLUDING INCLINED CHIPS AND METHOD OF FABRICATING THE SAME

(71) Applicant: SAMSUNG ELECTRONICS CO., LTD., Suwon-si (KR)

(72) Inventors: Kyung Don Mun, Suwon-si (KR); Seokkyu Choi, Suwon-si (KR); Bongju Cho, Suwon-si (KR); Wooyoung Kim, Suwon-si (KR)

(73) Assignee: SAMSUNG ELECTRONICS CO., LTD., Suwon-si (KR)

(21) Appl. No.: 19/441,159

(22) Filed: Jan. 6, 2026

(30) Foreign Application Priority Data
Apr. 22, 2025 (KR) 10-2025-0052535

(51) Int. Cl. H10W 72/20; H10W 90/00; H10W 90/22; H10B 80/00; H10D 80/30; H10W 72/00; H10W 74/15; H10W 90/10

(52) U.S. Cl. CPC H10W 72/227; H10W 72/257; H10W 90/22; H10W 90/401; H10W 90/724; H10B 80/00; H10D 80/30; H10W 72/823; H10W 74/15; H10W 90/10

(57) ABSTRACT

A semiconductor package may include: a first package including a first chip; a second chip above the first package in a first direction intersecting with an upper surface of the first package; and a third chip above the first package, the third chip spaced apart from the second chip in a second direction intersecting with the first direction. A height, in the first direction, from the upper surface of the first package to an upper surface of the second chip decreases with decreasing distance to the third chip in the second direction, and a height, in the first direction, from the upper surface of the first package to an upper surface of the third chip increases with increasing distance from the second chip in the second direction.

### CROSS-REFERENCE TO RELATED APPLICATIONS

This application claims the benefit of Korean Patent Application No. 10-2025-0052535, filed on Apr. 22, 2025, in the Korean Intellectual Property Office, the disclosure of which is incorporated herein by reference in its entirety.

### BACKGROUND

### Field

Some example embodiments of the present disclosure relate to a semiconductor package and a method of fabricating the same.

### Description of Related Art

Due to advancements in the electronics industry, demands for high functionality, high speed, and miniaturization of electronic components are increasing. In response to this tendency, a manner of stacking and mounting multiple semiconductor chips on one package wiring structure or a manner of stacking one package on another package may be used. For example, a package-in-package (PIP) type of semiconductor package or a package-on-package (POP) type of semiconductor package may be used.

While heat generated inside semiconductor packages may be dissipated to improve the performance of semiconductor packages, warpage caused by high integration of semiconductor packages may make it difficult to form a thermal interface material for heat dissipation.

### SUMMARY

According to some embodiments of the present disclosure, a semiconductor package in which heat dissipation performance is increased despite warpage may be provided.

According to some embodiments of the present disclosure, a semiconductor package may include: a first package including a first chip; a second chip above the first package in a first direction intersecting with an upper surface of the first package; and a third chip above the first package, the third chip spaced apart from the second chip in a second direction intersecting with the first direction, wherein a height, in the first direction, from the upper surface of the first package to an upper surface of the second chip decreases with decreasing distance to the third chip in the second direction, and wherein a height, in the first direction, from the upper surface of the first package to an upper surface of the third chip increases with increasing distance from the second chip in the second direction.

According to some embodiments of the present disclosure, a semiconductor package may include: a first package including a first chip; a second chip above the first package in a first direction intersecting with an upper surface of the first package, wherein the second chip is inclined with respect to the upper surface of the first package; and a third chip above the first package in the first direction and spaced apart from the second chip in a second direction intersecting with the first direction, wherein the third chip is inclined with respect to the upper surface of the first package, wherein a sign of a slope of an upper surface of the second chip with respect to the second direction is different from a sign of a slope of an upper surface of the third chip with respect to the second direction.

According to some embodiments of the present disclosure, a semiconductor package may include: a first redistribution structure; a first chip above the first redistribution structure and connected to the first redistribution structure; a first bumps connecting the first redistribution structure and the first chip; a second redistribution structure above the first chip; a wiring post connecting the first redistribution structure and the second redistribution structure; a molding layer on the first redistribution structure and at least partially surrounding the first chip and the wiring post; a second chip above the second redistribution structure in a first direction intersecting with an upper surface of the first chip; second bumps connecting the second redistribution structure and the second chip; a third chip above the second redistribution structure and spaced apart from the second chip in a second direction intersecting with the first direction, the third chip including a heat dissipation structure; and third bumps connecting the second redistribution structure and the third chip, wherein a height, in the first direction, of an innermost end of an upper surface of the second chip is smaller than a height, in the first direction, of an outermost end of the upper surface of the second chip, wherein the innermost end of the upper surface of the second chip is closest, among portions of the second chip, to the third chip in the second direction, and the outermost end of the upper surface of the second chip is spaced farthest apart, among the portions of the second chip, from the third chip in the second direction, wherein a height, in the first direction, of an innermost end of an upper surface of the third chip is smaller than a height, in the first direction, of an outermost end of the upper surface of the third chip, wherein the innermost end of the upper surface of the third chip is closest, among portions of the third chip, to the second chip in the second direction, and the outermost end of the upper surface of the third chip is spaced farthest apart, among the portions of the third chip, from the second chip in the second direction, wherein a thickness, in the first direction, of an innermost second bump closest, among the second bumps, to the innermost end of the upper surface of the second chip in the second direction is smaller than a thickness, in the first direction, of an outermost second bump closest, among the second bumps, to the outermost end of the upper surface of the second chip in the second direction, and wherein a thickness, in the first direction, of an innermost third bump closest, among the third bumps, to the innermost end of the upper surface of the third chip in the second direction is smaller than a thickness, in the first direction, of an outermost third bump closest, among the third bumps, to the outermost end of the upper surface of the third chip in the second direction.

Example embodiments are not limited to the aspects described above, and other unstated aspects of embodiments of the present disclosure may be clearly understood by those skilled in the art from the following description.

Details of non-limiting example embodiments are included in the detailed description and drawings.

### BRIEF DESCRIPTION OF DRAWINGS

These and/or other aspects, features, and advantages of embodiments of the present disclosure will become apparent and more readily appreciated from the following description of non-limiting example embodiments, taken in conjunction with the accompanying drawings of which:

FIG. 1 is an example layout diagram for illustrating a semiconductor package according to some example embodiments;

FIG. 2 is an example diagram showing a cross-section taken along a line A-A’ of FIG. 1;

FIG. 3 is an example enlarged view showing an area A1 of FIG. 2;

FIG. 4 is another example enlarged view showing the area A1 of FIG. 2;

FIG. 5 is another example diagram showing a cross-section taken along the line A-A’ of FIG. 1.

FIG. 6 is another example diagram showing a cross-section taken along the line A-A’ of FIG. 1;

FIG. 7 is another example diagram showing a cross-section taken along the line A-A’ of FIG. 1;

FIG. 8 is another example diagram showing a cross-section taken along the line A-A’ of FIG. 1;

FIG. 9 is an example enlarged view showing an area A2 of FIG. 8;

FIG. 10 is another example diagram showing a cross-section taken along the line A-A’ of FIG. 1;

FIG. 11 is an example enlarged view showing an area A3 of FIG. 10;

FIG. 12 is an example diagram for illustrating a semiconductor package according to some other example embodiments; and

FIGS. 13 to 17 are example diagrams of intermediate stages for illustrating a method of fabricating a semiconductor package according to some example embodiments.

### DETAILED DESCRIPTION

The words and terms used in the specification and claims are not to be construed as limited to general or dictionary meanings but construed as meanings and concepts coinciding with aspects of the present disclosure, based on the principle that the inventor may appropriately define the concept of the term to explain his or her own disclosure in the best way. Therefore, it may be understood that the example embodiments described herein and the configurations illustrated in the drawings are non-limiting example embodiments, and thus, may be replaced by various equivalents and modified examples present when this application is filed.

In the following description, a singular expression includes a plural expression unless otherwise defined by context. It should be understood that terms such as “comprise,” “include,” and “configure” are intended to indicate the presence of a feature, a number, a step, an operation, an element, a component, or a combination thereof described herein and not intended to exclude the possibility of the presence or addition of one or more other features, numbers, steps, operations, elements, components, or combinations thereof in advance.

In the present disclosure, a singular expression includes a plural expression unless otherwise defined by context. Furthermore, although the terms such as “first” and second may be used to describe various elements, these elements are not limited by the above terms, and the terms may be used to distinguish one element from another. Within the scope of the present disclosure, a first element may be referred to as a second element, and similarly, a second element may be referred to as a first element. Further, in the accompanying drawings, the shapes and sizes of elements may be exaggerated for clearer description.

Furthermore, expressions such as “above,” “upper portion,” “below,” “lower portion,” “side surface,” “front surface,” and “rear surface” are represented herein with respect to a direction illustrated in a drawing and may be represented otherwise if the direction of a corresponding element changes. The shapes and sizes of elements may be exaggerated for clarity in the drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, non-limiting example embodiments of the present disclosure are described with reference to the accompanying drawings.

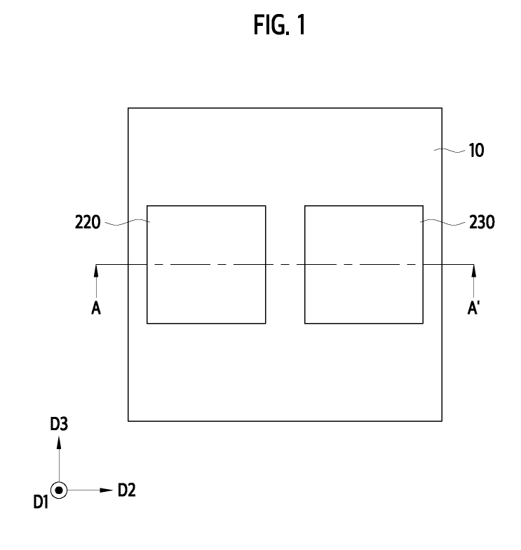

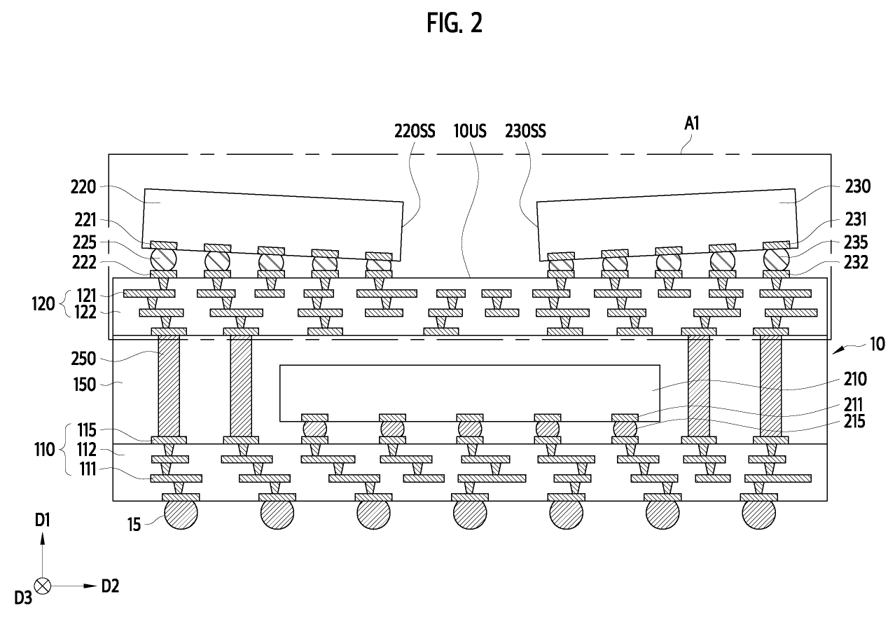

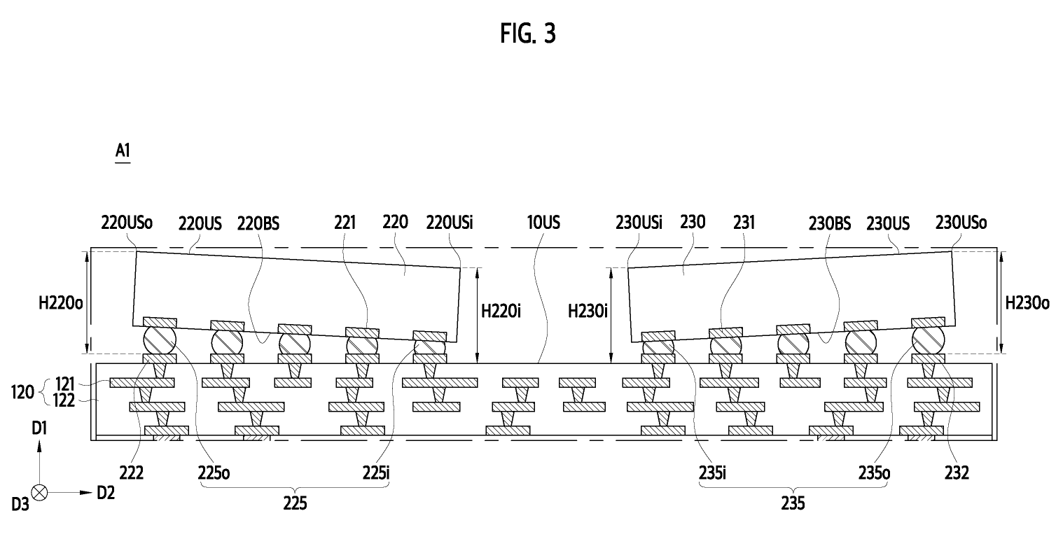

FIG. 1 is an example layout diagram for illustrating a semiconductor package according to some example embodiments. FIG. 2 is an example diagram showing a cross-section taken along a line A-A’ of FIG. 1. FIG. 3 is an example enlarged view showing an area A1 of FIG. 2.

Referring to FIGS. 1 to 3, a semiconductor package according to some example embodiments may include a first package 10 including a first chip 210, a second chip 220, and a third chip 230.

According to some example embodiments, the first package 10 may include a first redistribution structure 110, the first chip 210, a second redistribution structure 120, at least one wiring post 250, and a molding layer 150. The first package 10 may be disposed below the second chip 220 and the third chip 230.

According to some example embodiments, the first redistribution structure 110 may be a wiring structure for a package. For example, the first redistribution structure 110 may be a printed circuit board (PCB), a ceramic substrate, or an interposer. As another example, the first redistribution structure 110 may be a wiring structure for a wafer-level package (WLP) fabricated at a wafer level. As another example, the first redistribution structure 110 may be a front redistribution layer (FRDL) of a fan-out package.

According to some example embodiments, the first redistribution structure 110 may include a first redistribution metal layer 111, a first insulating layer 112, and at least one bonding pad 115.

According to some example embodiments, the first redistribution metal layer 111 may be disposed within the first insulating layer 112. The first redistribution metal layer 111 may include a wiring pattern and a wiring via connecting each wiring pattern. For example, the first redistribution metal layer 111 may be a multilayer structure in which two or more wiring patterns or two or more wiring vias are stacked alternately. The wiring pattern may be a portion for a horizontal connection between conductive components, and the wiring via may be a portion for a vertical connection between conductive components. For example, the wiring pattern may extend in a horizontal direction parallel to an upper surface of the first redistribution structure 110. The wiring via may connect wiring patterns spaced apart in a vertical direction intersecting with the upper surface of the first redistribution structure 110.

In some example embodiments, the first redistribution metal layer 111 may include a conductive material. For example, the first redistribution metal layer 111 may include, but is not limited to, copper (Cu), aluminum (Al), silver (Ag), tin (Sn), gold (Au), nickel (Ni), lead (Pb), titanium (Ti), or an alloy thereof.

According to some example embodiments, if the first redistribution structure 110 is the PCB, the first insulating layer 112 may include at least one material selected from among phenolic resin, an epoxy resin, and polyimide. The first insulating layer 112 may include at least one material selected from among tetrafunctional epoxy, polyphenylene ether, epoxy/polyphenylene oxide, bismaleimide triazine (BT), thermount, cyanate ester, and a liquid crystal polymer.

According to some example embodiments, the first insulating layer 112 may include a photoimageable dielectric. For example, the first insulating layer 112 may include a photoimageable polymer. The photoimageable polymer may be formed to be, for example, at least one from among photoimageable polyimide, polybenzoxazole, a phenol-based polymer, and a benzocyclobutene-based polymer. As another example, the first insulating layer 112 may be formed to be a silicon oxide layer, a silicon nitride layer, or a silicon oxynitride layer.

FIG. 2 illustrates that the first insulating layer 112 is a single layer, but the first insulating layer 112 may include a plurality of insulating layers that are stacked. Each of the plurality of insulating layers may surround the first redistribution metal layer 111.

According to some embodiments, a surface of the first insulating layer 112 may be covered by a solder resist. For example, a passivation layer may be formed on the surface of the first insulating layer 112. The passivation layer formed on the surface of the first insulating layer 112 may protect the first redistribution metal layer 111 and other structures from external impacts or moisture. The passivation layer may include the solder resist. However, embodiments of the present disclosure are not limited thereto.

According to some example embodiments, the at least one bonding pad 115 may be electrically connected to the first redistribution metal layer 111. The at least one bonding pad 115 may be disposed on the first insulating layer 112. The at least one bonding pad 115 may be exposed from the first insulating layer 112. The at least one bonding pad 115 may be disposed below a plurality of first bumps 215, to which the first chip 210 is connected, and the at least one wiring post 250. The bonding pad 115 may include a conductive material. For example, the bonding pad 115 may include, but is not limited to, copper (Cu), aluminum (Al), silver (Ag), tin (Sn), gold (Au), nickel (Ni), lead (Pb), titanium (Ti), or an alloy thereof.

According to some example embodiments, at least one external connection terminal 15 may be disposed below the first redistribution structure 110. The external connection terminal 15 may include a solder ball or a solder bump. The external connection terminal 15 may include a micro-bump. The external connection terminal 15 may be spherical or ellipsoidal but is not limited thereto. The number, gap, arrangement, and form of the external connection terminal 15 are not limited to the drawings and may vary depending on embodiment. The external connection terminal 15 may include, for example, tin (Sn), indium (In), bismuth (Bi), antimony (Sb), copper (Cu), silver (Ag), zinc (Zn), lead (Pb), and a combination thereof, but is not limited thereto.

According to some example embodiments, the first chip 210 may be disposed above the first redistribution structure 110. The first chip 210 may be connected to the first redistribution structure 110. The first chip 210 may be flip-chip bonded to the first redistribution structure 110. With respect to the first redistribution structure 110, a height (or vertical level) of an upper surface of the first chip 210 may be lower than heights (or vertical levels) of upper surfaces of a plurality of wiring posts 250. The first chip 210 may be formed above the first redistribution structure 110 such that the upper surface of the first chip 210 is closer than the upper surfaces of the plurality of wiring posts 250 to the first redistribution structure 110.

According to some example embodiments, the first chip 210 may be surrounded by the plurality of wiring posts 250. For example, when viewed in a direction facing the upper surface of the first chip 210, the plurality of wiring posts 250 may be disposed outside the first chip 210 to surround the first chip 210. For example, the plurality of wiring posts 250 may surround the first chip 210 in horizontal directions (e.g., a second direction D2 and/or a third direction D3). The first chip 210 may be disposed at a central portion, and the plurality of wiring posts 250 may be disposed around the first chip 210 and along an edge of the first redistribution structure 110.

According to some example embodiments, the first chip 210 may include a plurality of first lower pads 211. The first chip 210 may be bonded to the bonding pads 115 through the plurality of first bumps 215 disposed below the plurality of first lower pads 211. Each of the plurality of first lower pads 211 and each of the plurality of first bumps 215 may include a conductive material. For example, each of the plurality of first lower pads 211 and each of the plurality of first bumps 215 may include, but is not limited to, copper (Cu), aluminum (Al), silver (Ag), tin (Sn), gold (Au), nickel (Ni), lead (Pb), titanium (Ti), or an alloy thereof. The plurality of first bumps 215 may have, for example, a pillar structure or a solder ball structure, but are not limited thereto.

According to some example embodiments, the first chip 210 may be an integrated circuit (IC) in which hundreds to millions or more of semiconductor elements are integrated within a single chip. The first chip 210 may include a logic chip. The first chip 210 may be a central processing unit (CPU), a graphic processing unit (GPU), a field-programmable gate array (FPGA), a digital signal processor, an encryption processor, a microprocessor, a microcontroller, or an application processor (AP), but is not limited thereto. For example, the first chip 210 may be an analog-digital converter (ADC) or a logic chip such as an application-specific IC (ASIC). As another example, the first chip 210 may be a memory chip such as volatile memory (e.g., dynamic random access memory (DRAM)) and non-volatile memory (e.g., read only memory (ROM) or flash memory). Further, the first chip 210 may be configured as a combination thereof.

According to some example embodiments, the second redistribution structure 120 may be connected to the at least one wiring post 250. The second redistribution structure 120 may be disposed above the first chip 210. The second redistribution structure 120 may be spaced apart from the first redistribution structure 110 in a first direction D1 with the first chip 210 and the molding layer 150 in between the second redistribution structure 120 and the first redistribution structure 110. The first direction D1 may be a direction intersecting with an upper surface 10US of the first package 10. The first direction D1 may be a direction intersecting with an upper surface or a lower surface of the first redistribution structure 110 or the second redistribution structure 120.

According to some example embodiments, the second redistribution structure 120 may include a second redistribution metal layer 121 and a second insulating layer 122. A description of the second redistribution metal layer 121 and the second insulating layer 122 is substantially identical to a description of the first redistribution metal layer 111 and the first insulating layer 112, and thus, repeated descriptions thereof may be omitted.

According to some example embodiments, the at least one wiring post 250 may extend between the first redistribution structure 110 and the second redistribution structure 120. The at least one wiring post 250 may connect the first redistribution structure 110 and the second redistribution structure 120. The at least one wiring post 250 may extend in the first direction D1. The at least one wiring post 250 may penetrate the molding layer 150. The wiring post 250 may include a metal material such as titanium (Ti), copper (Cu), aluminum (Al), silver (Ag), tin (Sn), gold (Au), nickel (Ni), lead (Pb), and an alloy thereof.

According to some example embodiments, the molding layer 150 may surround the first chip 210 and the at least one wiring post 250. For example, the molding layer 150 may surround the first chip 210 and the at least one wiring post in horizontal directions (e.g., the second direction and/or the third direction) and/or vertical direction (e.g., the first direction). The molding layer 150 may cover the first chip 210. The molding layer 150 may not cover the upper surfaces of the plurality of wiring posts 250.

According to some example embodiments, the molding layer 150 may include an insulating material. For example, the molding layer 150 may include an insulating polymer material such as an epoxy molding compound (EMC). As another example, the molding layer 150 may include a thermosetting resin such as an epoxy resin or a thermoplastic resin such as polyimide.

According to some example embodiments, the second chip 220 may be disposed above the first package 10. The second chip 220 may be connected to the first package 10 in the first direction D1. The second chip 220 may be disposed above the second redistribution structure 120 in the first direction D1. The second chip 220 may be electrically connected to the second redistribution structure 120. The second chip 220 may be flip-chip bonded to the second redistribution structure 120. The second chip 220 may be disposed to be spaced apart from the third chip 230 in a second direction D2.

According to some example embodiments, the second chip 220 may be an IC in which hundreds to millions or more of semiconductor elements are integrated within a single chip. The second chip 220 may include a memory chip. For example, the second chip 220 may include volatile memory (e.g., DRAM) or non-volatile memory (e.g., ROM or flash memory). The second chip 220 may include high bandwidth memory (HBM). As another example, the second chip 220 may be a CPU, a GPU, an FPGA, a digital signal processor, an encryption processor, a microprocessor, a microcontroller, or an AP, but is not limited thereto. The second chip 220 may be an ADC or a logic chip such as an ASIC. Further, the second chip 220 may be configured as a combination thereof.

According to some example embodiments, the second chip 220 may be disposed to be inclined with respect to the upper surface 10US of the first package 10. The second chip 220 may be disposed to be inclined with respect to an upper surface of the second redistribution structure 120. For example, an upper surface 220US and a lower surface 220BS of the second chip 220 may not be parallel to the upper surface 10US of the first package 10 and may have a slope with respect to the upper surface 10US of the first package 10. The upper surface 220US and the lower surface 220BS of the second chip 220 may be inclined away from the third chip 230. A height from the upper surface 10US of the first package 10 to the upper surface 220US of the second chip 220 in the first direction D1 may decrease with decreasing distance to the third chip 230 in the second direction D2. A height from the upper surface of the second redistribution structure 120 to the upper surface 220US of the second chip 220 in the first direction D1 may decrease with decreasing distance to the third chip 230 in the second direction D2. A height from the upper surface 10US of the first package 10 to the lower surface 220BS of the second chip 220 in the first direction D1 may decrease with decreasing distance to the third chip 230 in the second direction D2. A height from the upper surface of the second redistribution structure 120 to the lower surface 220BS of the second chip 220 in the first direction D1 may decrease with decreasing distance to the third chip 230 in the second direction D2.

According to some example embodiments, the upper surface 220US of the second chip 220 may include an innermost end 220USi disposed closest, among portions of the second chip 220, to the third chip 230 in the second direction D2 and an outermost end 220USo spaced farthest apart, among portions of the second chip 220, from the third chip 230 in the second direction D2. With respect to the upper surface 10US of the first package 10, a height H220i of the innermost end 220USi of the upper surface 220US of the second chip 220 in the first direction D1 may be different from a height H220o of the outermost end 220USo of the upper surface 220US of the second chip 220. With respect to the upper surface 10US of the first package 10, the height H220i of the innermost end 220USi of the upper surface 220US of the second chip 220 in the first direction D1 may be smaller than the height H220o of the outermost end 220USo of the upper surface 220US of the second chip 220. With respect to the upper surface 10US of the first package 10, a difference between the height H220i of the innermost end 220USi of the upper surface 220US of the second chip 220 in the first direction D1 and the height H220o of the outermost end 220USo of the upper surface 220US of the second chip 220 may be 30 micrometers (um) to 100 um.

According to some example embodiments, a side surface 220SS of the second chip 220 may extend at a non-perpendicular angle with respect to the upper surface 10US of the first package 10. The side surface 220SS of the second chip 220 may extend at a non-perpendicular angle with respect to the upper surface of the second redistribution structure 120. For example, the side surface 220SS of the second chip 220 may be inclined at a predetermined angle with respect to the first direction D1. A sign of a slope of the side surface 220SS of the second chip 220 with respect to the second direction D2 may be different from a sign of a slope of a side surface 230SS of the third chip 230 with respect to the second direction D2. The side surface 220SS of the second chip 220 may be inclined toward the third chip 230.

According to some example embodiments, the second chip 220 may be connected to the second redistribution structure 120 through a plurality of second bumps 225. The plurality of second bumps 225 may be disposed between the second chip 220 and the first package 10. The plurality of second bumps 225 may be disposed between the second redistribution structure 120 and the second chip 220. The plurality of second bumps 225 may be disposed between a plurality of second upper pads 221 and a plurality of second lower pads 222.

According to some example embodiments, the plurality of second upper pads 221 may be disposed at (e.g., in or on) the lower surface 220BS of the second chip 220. The plurality of second upper pads 221 may be disposed on the plurality of second bumps 225. The plurality of second lower pads 222 may be disposed at (e.g., in or on) the upper surface of the second redistribution structure 120. The plurality of second lower pads 222 may be disposed at (e.g., in or on) the upper surface 10US of the first package 10. The plurality of second lower pads 222 may be disposed below the plurality of second bumps 225. The plurality of second lower pads 222 may be electrically connected to the second redistribution metal layer 121 of the second redistribution structure 120.

According to some example embodiments, each of the plurality of second upper pads 221, each of the plurality of second lower pads 222, and each of the plurality of second bumps 225 may include a conductive material. For example, each of the plurality of second upper pads 221, each of the plurality of second lower pads 222, and each of the plurality of second bumps 225 may include, but is not limited to, copper (Cu), aluminum (Al), silver (Ag), tin (Sn), gold (Au), nickel (Ni), lead (Pb), titanium (Ti), or an alloy thereof. The plurality of second bumps 225 may have, for example, a pillar structure or a solder ball structure, but are not limited thereto.

According to some example embodiments, thicknesses of the plurality of second bumps 225 in the first direction D1 may be different from each other in the second direction D2. The thicknesses of the plurality of second bumps 225 in the first direction D1 may decrease with decreasing distance to the third chip 230 in the second direction D2. The plurality of second bumps 225 may include an innermost second bump 225i disposed closest, among the second bumps 225, to the third chip 230 in the second direction D2, and an outermost second bump 225o disposed to be spaced farthest apart, among the second bumps 225, from the third chip 230 in the second direction D2. A thickness of the innermost second bump 225i in the first direction D1 may be smaller than a thickness of the outermost second bump 225o in the first direction D1. Therefore, the second chip 220 connected to the plurality of second bumps 225 that decrease in thickness in the first direction D1 with decreasing distance to the third chip 230 in the second direction D2 may have a slope with respect to the second direction D2 and be disposed above the first package 10. The plurality of second bumps 225 may have the same mass or the same volume as each other. Even though the plurality of second bumps 225 may have different thicknesses in the first direction D1, the plurality of second bumps 225 may have the same mass or the same volume as each other.

According to some example embodiments, contact areas between the plurality of second lower pads 222 and the plurality of second bumps 225 may increase with decreasing distance to the third chip 230 in the second direction D2. For example, a contact area between the innermost second bump 225i and one of the plurality of second lower pads 222 may be greater than a contact area between the outermost second bump 225o and one of the plurality of second lower pads 222. As the plurality of second bumps 225 are further pressed in the first direction D1 between the first package 10 and the second chip 220 toward the second direction D2, the contact areas with the plurality of second lower pads 222 may increase.

According to some example embodiments, the third chip 230 may be disposed above the first package 10. The third chip 230 may be connected to the first package 10 in the first direction D1. The third chip 230 may be disposed above the second redistribution structure 120 in the first direction D1. The third chip 230 may be electrically connected to the second redistribution structure 120. The third chip 230 may be flip-chip bonded to the second redistribution structure 120. The third chip 230 may be disposed to be spaced apart from the second chip 220 in the second direction D2.

According to some example embodiments, the third chip 230 may be an IC in which hundreds to millions or more of semiconductor elements are integrated within a single chip. The third chip 230 may include a memory chip. For example, the third chip 230 may include volatile memory (e.g., DRAM) or non-volatile memory (e.g., ROM or flash memory). The third chip 230 may include HBM. As another example, the third chip 230 may be a CPU, a GPU, an FPGA, a digital signal processor, an encryption processor, a microprocessor, a microcontroller, or an AP, but is not limited thereto. The third chip 230 may be an ADC or a logic chip such as an ASIC. Further, the third chip 230 may be configured as a combination thereof.

According to some example embodiments, the third chip 230 may include a heat dissipation structure. For example, the third chip 230 may include a heat path block. As another example, the third chip 230 may include a heat slug. The third chip 230 may dissipate, spread, or conduct heat generated from the first package 10 to the outside. The third chip 230 may include a material with high thermal conductivity such as, for example, aluminum (Al), gold (Au), silver (Ag), copper (Cu), iron (Fe), graphite, or graphene.

According to some example embodiments, the third chip 230 may be disposed to be inclined with respect to the upper surface 10US of the first package 10. The third chip 230 may be disposed to be inclined with respect to the upper surface of the second redistribution structure 120. For example, an upper surface 230US and a lower surface 230BS of the third chip 230 may not be parallel to the upper surface 10US of the first package 10 and may have a slope with respect to the upper surface 10US of the first package 10. The upper surface 230US and the lower surface 230BS of the third chip 230 may be inclined away from the second chip 220. A height from the upper surface 10US of the first package 10 to the upper surface 230US of the third chip 230 in the first direction D1 may increase with increasing distance from the second chip 220 in the second direction D2. A height from the upper surface of the second redistribution structure 120 to the upper surface 230US of the third chip 230 in the first direction D1 may increase with increasing distance from the second chip 220 in the second direction D2. A height from the upper surface 10US of the first package 10 to the lower surface 230BS of the third chip 230 in the first direction D1 may increase with increasing distance from the second chip 220 in the second direction D2. A height from the upper surface of the second redistribution structure 120 to the lower surface 230BS of the third chip 230 in the first direction D1 may increase with increasing distance from the second chip 220 in the second direction D2.

According to some example embodiments, the upper surface 230US of the third chip 230 may include an innermost end 230USi disposed closest, among portions of the third chip 230, to the second chip 220 in the second direction D2, and an outermost end 230USo spaced farthest apart, among portions of the third chip 230, from the second chip 220 in the second direction D2. With respect to the upper surface 10US of the first package 10, a height H230i of the innermost end 230USi of the upper surface 230US of the third chip 230 in the first direction D1 may be different from a height H230o of the outermost end 230USo of the upper surface 230US of the third chip 230. With respect to the upper surface 10US of the first package 10, the height H230i of the innermost end 230USi of the upper surface 230US of the third chip 230 in the first direction D1 may be smaller than the height H230o of the outermost end 230USo of the upper surface 230US of the third chip 230. With respect to the upper surface 10US of the first package 10, a difference between the height H230i of the innermost end 230USi of the upper surface 230US of the third chip 230 in the first direction D1 and the height H230o of the outermost end 230USo of the upper surface 230US of the third chip 230 may be 30 um to 100 um.

According to some example embodiments, slopes of the second chip 220 and the third chip 230 inclined away from each other may be identical. For example, with respect to the upper surface 10US of the first package 10, the height H220i of the innermost end 220USi of the upper surface 220US of the second chip 220 in the first direction D1 and the height H230i of the innermost end 230USi of the upper surface 230US of the third chip 230 in the first direction D1 may be identical. With respect to the upper surface 10US of the first package 10, the height H220o of the outermost end 220USo of the upper surface 220US of the second chip 220 in the first direction D1 and the height H230o of the outermost end 230USo of the upper surface 230US of the third chip 230 in the first direction D1 may be identical. However, example embodiments are not limited thereto.

According to some example embodiments, the side surface 230SS of the third chip 230 may extend at a non-perpendicular angle with respect to the upper surface 10US of the first package 10. For example, the side surface 230SS of the third chip 230 may be inclined at a predetermined angle with respect to the first direction D1. The sign of the slope of the side surface 230SS of the third chip 230 with respect to the second direction D2 may be different from the sign of the slope of the side surface 220SS of the second chip 220 with respect to the second direction D2. The side surface 220SS of the second chip 220 may have a slope smaller than 90 degrees with respect to the second direction D2, and the side surface 230SS of the third chip 230 may have a slope greater than 90 degrees with respect to the second direction D2. The side surface 230SS of the third chip 230 may be inclined toward the second chip 220. A distance in the second direction D2 between the side surface 220SS of the second chip 220 and the side surface 230SS of the third chip 230, which face each other in the second direction D2, may decrease with increasing distance from the upper surface 10US of the first package 10 in the first direction D1. The distance in the second direction D2 between the side surface 220SS of the second chip 220 and the side surface 230SS of the third chip 230, which face each other, may decrease with increasing distance from the upper surface of the second redistribution structure 120 in the first direction D1.

According to some example embodiments, the third chip 230 may be connected to the second redistribution structure 120 through a plurality of third bumps 235. The plurality of third bumps 235 may be disposed between the second redistribution structure 120 and the third chip 230. The plurality of third bumps 235 may be disposed between the third chip 230 and the first package 10. The plurality of third bumps 235 may be disposed between a plurality of third upper pads 231 and a plurality of third lower pads 232.

According to some example embodiments, the plurality of third upper pads 231 may be disposed at (e.g., in or on) the lower surface 230BS of the third chip 230. The plurality of third upper pads 231 may be disposed on the plurality of third bumps 235. The plurality of third lower pads 232 may be disposed at (e.g., in or on) the upper surface of the second redistribution structure 120. The plurality of third lower pads 232 may be disposed at (e.g., in or on) the upper surface 10US of the first package 10. The plurality of third lower pads 232 may be spaced apart from the plurality of second lower pads 222 in the second direction D2. The plurality of third lower pads 232 may be disposed below the plurality of third bumps 235. The plurality of third lower pads 232 may be electrically connected to the second redistribution metal layer 121 of the second redistribution structure 120.

According to some example embodiments, each of the plurality of third upper pads 231, each of the plurality of third lower pads 232, and each of the plurality of third bumps 235 may include a conductive material. For example, each of the plurality of third upper pads 231, each of the plurality of third lower pads 232, and each of the plurality of third bumps 235 may include, but is not limited to, copper (Cu), aluminum (Al), silver (Ag), tin (Sn), gold (Au), nickel (Ni), lead (Pb), titanium (Ti), or an alloy thereof. The plurality of third bumps 235 may have, for example, a pillar structure or a solder ball structure, but are not limited thereto.

According to some example embodiments, thicknesses of the plurality of third bumps 235 in the first direction D1 may be different from each other in the second direction D2. The thicknesses of the plurality of third bumps 235 in the first direction D1 may increase with increasing distance from the second chip 220 in the second direction D2. The plurality of third bumps 235 may include an innermost third bump 235i disposed closest to the second chip 220, among the third bumps 235, in the second direction D2, and an outermost third bump 235o disposed to be spaced farthest apart, among the third bumps 235, from the second chip 220 in the second direction D2. A thickness of the innermost third bump 235i in the first direction D1 may be smaller than a thickness of the outermost third bump 235o in the first direction D1. Therefore, the third chip 230 connected to the plurality of third bumps 235 that increase in thickness in the first direction D1 with increasing distance from the second chip 220 in the second direction D2 may have a slope with respect to the second direction D2 and be disposed above the first package 10. The plurality of third bumps 235 may have the same mass or the same volume as each other. Even though the plurality of third bumps 235 may have different thicknesses in the first direction D1, the plurality of third bumps 235 may have the same mass or the same volume as each other.

According to some example embodiments, contact areas between the plurality of third lower pads 232 and the plurality of third bumps 235 may decrease with increasing distance from the second chip 220 in the second direction D2. For example, a contact area between the innermost third bump 235i and one of the plurality of third lower pads 232 may be greater than a contact area between the outermost third bump 235o and one of the plurality of third lower pads 232. As the plurality of third bumps 235 are less pressed in the first direction D1 between the first package 10 and the third chip 230 toward the second direction D2, the contact areas with the plurality of third lower pads 232 may decrease.

According to some example embodiments, a sign of a slope of the upper surface 220US of the second chip 220 with respect to the second direction D2 and a sign of a slope of the upper surface 230US of the third chip 230 with respect to the second direction D2 may be different from each other. For example, the upper surface 220US of the second chip 220 may have a slope greater than 90 degrees and smaller than 180 degrees with respect to the second direction D2. The upper surface 230US of the third chip 230 may have a slope greater than 0 degree and smaller than 90 degrees with respect to the second direction D2.

According to some example embodiments, a distance in the second direction D2 between the upper surface 220US of the second chip 220 and the upper surface 230US of the third chip 230 may increase with increasing distance from the first package 10 in the first direction D1. The distance in the second direction D2 between the upper surface 220US of the second chip 220 and the upper surface 230US of the third chip 230 may increase with increasing distance from the second redistribution structure 120 in the first direction D1. This may be attributed to the second chip 220 and the third chip 230 being disposed to be inclined. Since the upper surface 220US of the second chip 220 is inclined away from the third chip 230 and the upper surface 230US of the third chip 230 is inclined away from the second chip 220, the distance in the second direction D2 between the upper surface 220US of the second chip 220 and the upper surface 230US of the third chip 230 may increase with increasing distance from the upper surface 10US of the first package 10 in the first direction D1.

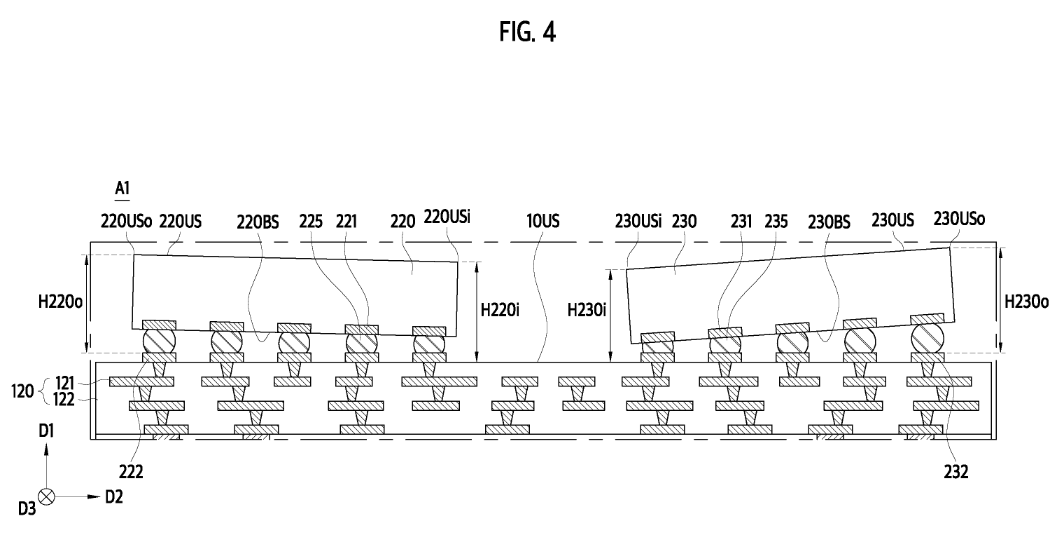

FIG. 4 is another example enlarged view showing the area A1 of FIG. 2. To facilitate understanding of the present disclosure, the difference from what is described with reference to FIGS. 1 to 3 is mainly described.

Referring to FIG. 4, slopes of the second chip 220 and the third chip 230 inclined away from each other may be different. With respect to the upper surface of the second redistribution structure 120, the height H220i of the innermost end 220USi of the upper surface 220US of the second chip 220 in the first direction D1 and the height H230i of the innermost end 230USi of the upper surface 230US of the third chip 230 in the first direction D1 may be different from each other. With respect to the upper surface 10US of the first package 10, the height H220i of the innermost end 220USi of the upper surface 220US of the second chip 220 in the first direction D1 and the height H230i of the innermost end 230USi of the upper surface 230US of the third chip 230 in the first direction D1 may be different from each other. For example, with respect to the upper surface 10US of the first package 10, the height H220i of the innermost end 220USi of the upper surface 220US of the second chip 220 in the first direction D1 may be greater than the height H230i of the innermost end 230USi of the upper surface 230US of the third chip 230 in the first direction D1.

According to some example embodiments, with respect to the upper surface of the second redistribution structure 120, the height H220o of the outermost end 220USo of the upper surface 220US of the second chip 220 in the first direction D1 and the height H230o of the outermost end 230USo of the upper surface 230US of the third chip 230 in the first direction D1 may be different from each other. With respect to the upper surface 10US of the first package 10, the height H220o of the outermost end 220USo of the upper surface 220US of the second chip 220 in the first direction D1 and the height H230o of the outermost end 230USo of the upper surface 230US of the third chip 230 in the first direction D1 may be different from each other. For example, with respect to the upper surface 10US of the first package 10, the height H220o of the outermost end 220USo of the upper surface 220US of the second chip 220 in the first direction D1 may be smaller than the height H230o of the outermost end 230USo of the upper surface 230US of the third chip 230 in the first direction D1.

FIG. 4 illustrates that with respect to the upper surface 10US of the first package 10, the third chip 230 is inclined more than the second chip 220, but example embodiments are not limited thereto. For example, with respect to the upper surface 10US of the first package 10, the height H220i of the innermost end 220USi of the upper surface 220US of the second chip 220 in the first direction D1 may be smaller than the height H230i of the innermost end 230USi of the upper surface 230US of the third chip 230 in the first direction D1, and the height H220o of the outermost end 220USo of the upper surface 220US of the second chip 220 in the first direction D1 may be greater than the height H230o of the outermost end 230USo of the upper surface 230US of the third chip 230 in the first direction D1.

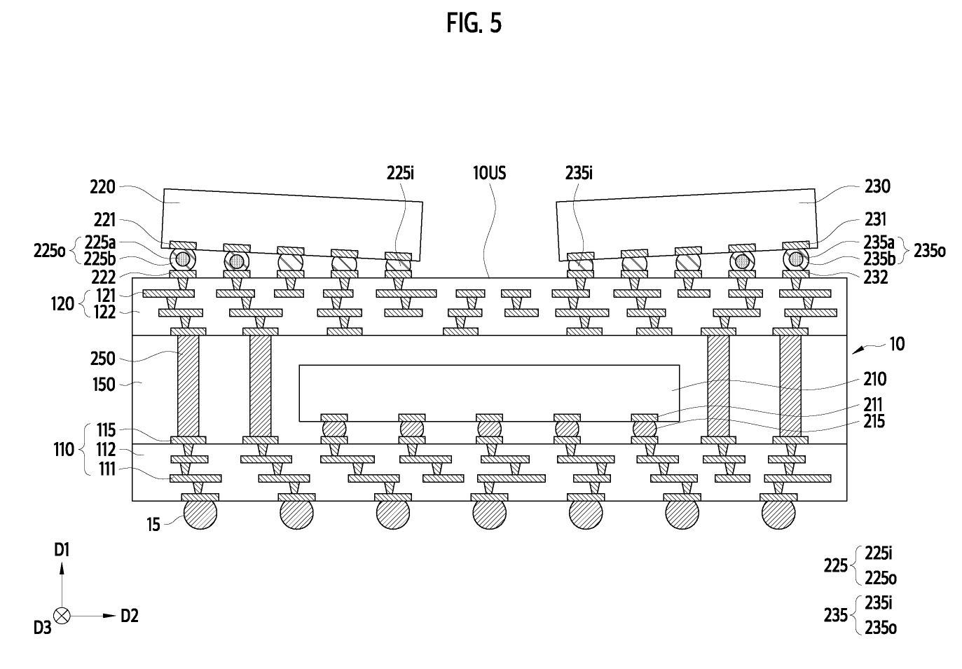

FIG. 5 is another example diagram showing a cross-section taken along the line A-A’ of FIG. 1. To facilitate understanding of the present disclosure, the difference from what is described with reference to FIGS. 1 to 3 is mainly described.

Referring to FIG. 5, at least some of the plurality of second bumps 225 may include multiple layers. The outermost second bump 225o may include multiple layers, and the innermost second bump 225i may include only a single layer. In addition to the outermost second bump 225o, at least one or more second bumps 225 adjacent to the outermost second bump 225o in the second direction D2 may include multiple layers. The outermost second bump 225o may include a material different from a material of the innermost second bump 225i.

According to some example embodiments, the outermost second bump 225o may include a first layer 225a and a second layer 225b. The first layer 225a may be surrounded by the second layer 225b. The first layer 225a may include a material different from a material of the second layer 225b. The first layer 225a may include copper (Cu). The second layer 225b may include a material identical to a material of the innermost second bump 225i. For example, the second layer 225b and the single layer of the innermost second bump 225i may include lead (Pb).

According to some example embodiments, at least some of the plurality of third bumps 235 may include multiple layers. The outermost third bump 235o may include multiple layers, and the innermost third bump 235i may include only a single layer. In addition to the outermost third bump 235o, at least one or more third bumps 235 adjacent to the outermost third bump 235o in the second direction D2 may include multiple layers.

According to some example embodiments, the outermost third bump 235o may include a third layer 235a and a fourth layer 235b. The third layer 235a may be surrounded by the fourth layer 235b. The third layer 235a may include a material different from a material of the fourth layer 235b. The third layer 235a may include copper (Cu). The fourth layer 235b may include a material identical to a material of the innermost third bump 235i. For example, the fourth layer 235b and the single layer of the innermost third bump 235i may include lead (Pb).

According to some example embodiments, the plurality of second bumps 225 and the plurality of third bumps 235, which include multiple layers, may be deformed less by pressure than the plurality of second bumps 225 and the plurality of third bumps 235, which include only a single layer. Therefore, as the plurality of second bumps 225 including the outermost second bump 225o and the plurality of third bumps 235 including the outermost third bump 235o include multiple layers, and the plurality of second bumps 225 including the innermost second bump 225i and the plurality of third bumps 235 including the innermost third bump 235i include only a single layer, the second chip 220 and the third chip 230 may be formed to be inclined when the second chip 220 and the third chip 230 are bonded to the first package 10.

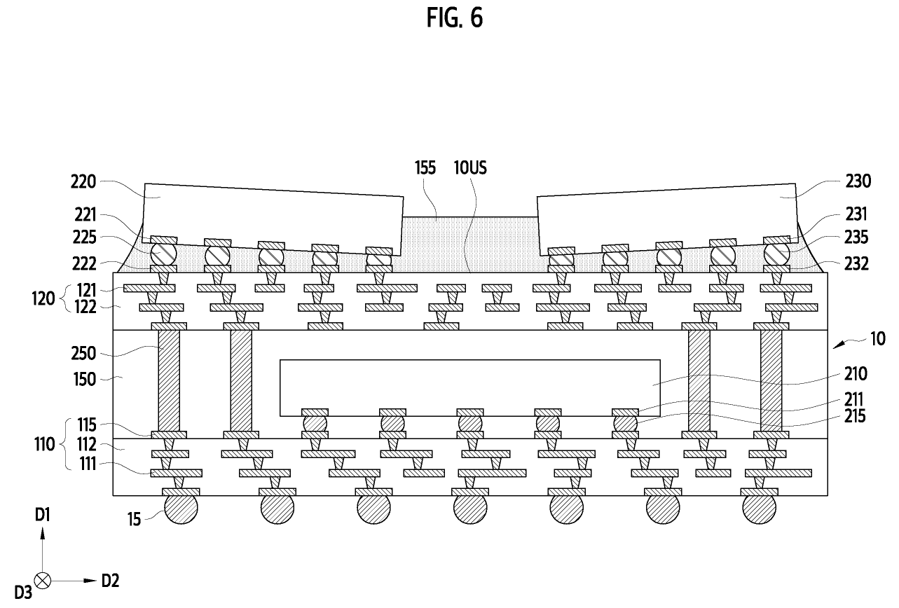

FIG. 6 is another example diagram showing a cross-section taken along the line A-A’ of FIG. 1. To facilitate understanding of the present disclosure, the difference from what is described with reference to FIGS. 1 to 3 is mainly described.

The semiconductor package according to some example embodiments may further include an underfill 155. The underfill 155 may be disposed below the second chip 220 and the third chip 230. The underfill 155 may be disposed on the first package 10. The underfill 155 may be disposed on the second redistribution structure 120. The underfill 155 may surround the plurality of second bumps 225 and the plurality of third bumps 235. The underfill 155 may cover at least a portion of a side surface of the second chip 220 and at least a portion of a side surface of the third chip 230. The underfill 155 may include, for example, an epoxy-based resin, benzocyclobutene, or polyimide, but is not limited thereto. For example, the underfill 155 may further include a silica filler. As another example, the underfill 155 may include an adhesive and a flux. As another example, the underfill 155 may include the silica filler or the flux.

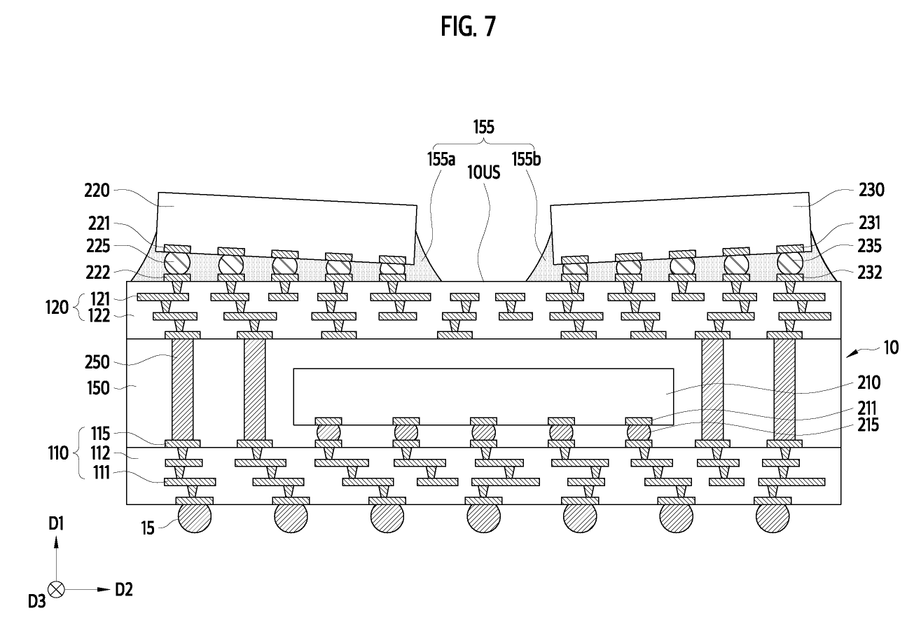

FIG. 7 is another example diagram showing a cross-section taken along the line A-A’ of FIG. 1. To facilitate understanding of the present disclosure, the difference from what is described with reference to FIG. 6 is mainly described.

Referring to FIG. 7, the underfill 155 may include a first underfill 155a and a second underfill 155b. The first underfill 155a and the second underfill 155b may be spaced apart from each other. The upper surface 10US of the first package 10 may be exposed between the first underfill 155a and the second underfill 155b. The first underfill 155a may be disposed below the second chip 220. The first underfill 155a may be disposed below the second chip 220 to surround the plurality of second bumps 225. The second underfill 155b may be disposed below the third chip 230. The second underfill 155b may be disposed below the third chip 230 to surround the plurality of third bumps 235.

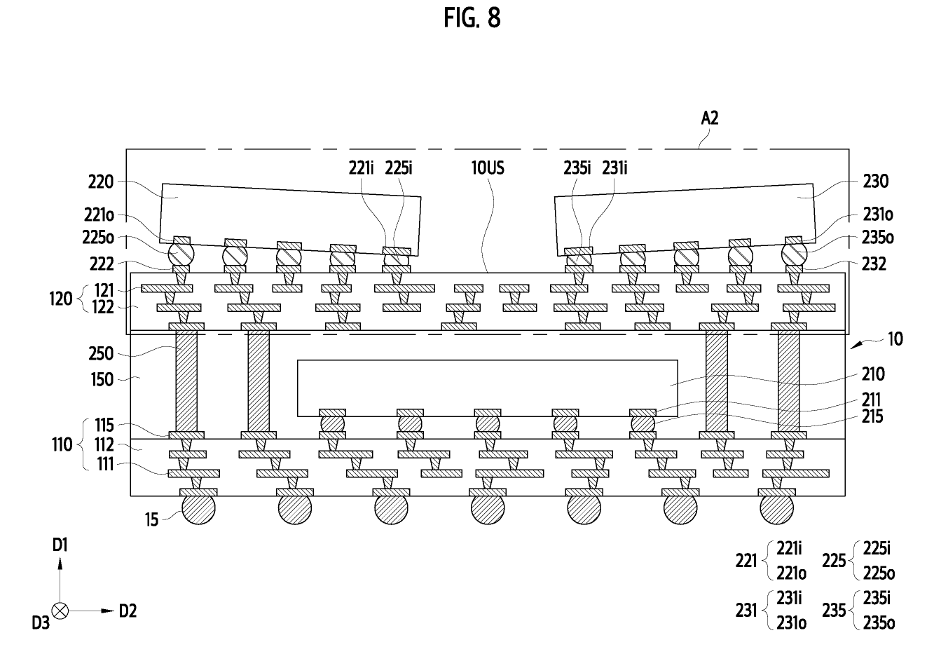

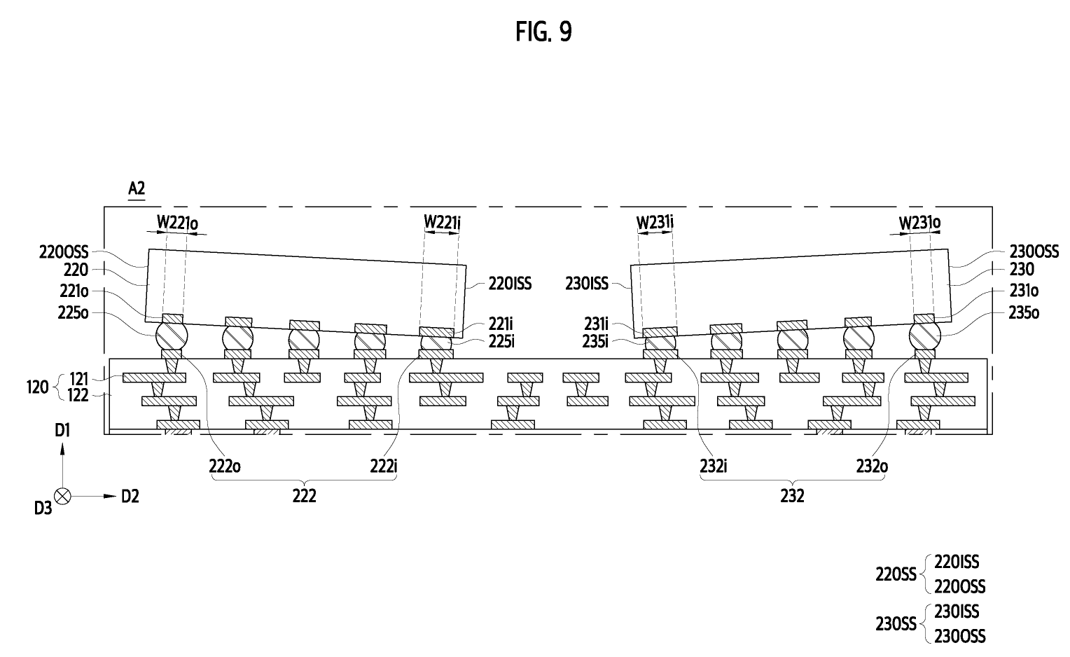

FIG. 8 is another example diagram showing a cross-section taken along the line A-A’ of FIG. 1. FIG. 9 is an example enlarged view showing an area A2 of FIG. 8. To facilitate understanding of the present disclosure, the difference from what is described with reference to FIGS. 1 to 3 is mainly described.

Referring to FIGS. 8 and 9, widths of the plurality of second upper pads 221 may vary in the second direction D2. The widths of the plurality of second upper pads 221 may increase with decreasing distance to the third chip 230 in the second direction D2. The widths of the plurality of second upper pads 221 may refer to widths of the plurality of second upper pads 221 at (e.g., in or on) a lower surface of the second chip 220. The plurality of second upper pads 221 may include an innermost second upper pad 221i disposed closest, among the second upper pads 221, to the third chip 230 in the second direction D2, and an outermost second upper pad 221o disposed to be spaced farthest apart, among the second upper pads 221, from the third chip 230 in the second direction D2. A width W221i of the innermost second upper pad 221i may be greater than a width W221o of the outermost second upper pad 221o.

According to some example embodiments, widths of the plurality of second lower pads 222 may vary in the second direction D2. The widths of the plurality of second lower pads 222 may increase with decreasing distance to the third chip 230 in the second direction D2. The widths of the plurality of second lower pads 222 may refer to widths of the plurality of second lower pads 222 at (e.g., in or on) the upper surface 10US of the first package 10. The plurality of second lower pads 222 may include an innermost second lower pad 222i disposed closest, among the second lower pads 222, to the third chip 230 in the second direction D2, and an outermost second lower pad 222o disposed to be spaced farthest apart, among the second lower pads 222, from the third chip 230 in the second direction D2. A width of the innermost second lower pad 222i may be greater than a width of the outermost second lower pad 222o.

According to some example embodiments, since the width W221i of the innermost second upper pad 221i is greater than the width W221o of the outermost second upper pad 221o, a contact area between the innermost second upper pad 221i and the innermost second bump 225i may be greater than a contact area between the outermost second upper pad 221o and the outermost second bump 225o. Since the width of the innermost second lower pad 222i is greater than the width of the outermost second lower pad 222o, a contact area between the innermost second lower pad 222i and the innermost second bump 225i may be greater than a contact area between the outermost second lower pad 222o and the outermost second bump 225o.

According to some example embodiments, even though the plurality of second bumps 225 may have the same mass or the same volume as each other, greater contact areas of the plurality of second bumps 225 with the plurality of second upper pads 221 and the plurality of second lower pads 222 may lead to a greater degree to which the plurality of second bumps 225 are deformed when the second chip 220 is bonded to the plurality of second lower pads 222 via the plurality of second bumps 225 and the plurality of second upper pads 221. For example, greater widths of the plurality of second upper pads 221 or the plurality of second lower pads 222 may increase at least some portions of the plurality of second bumps 225, which are inserted into trenches formed by the plurality of second upper pads 221 or the plurality of second lower pads 222. As another example, greater widths of the plurality of second upper pads 221 or the plurality of second lower pads 222 may lead to a greater degree to which the plurality of second bumps 225 are deformed in the first direction D1 based on the plurality of second bumps 225 being bonded to the plurality of second upper pads 221 or the plurality of second lower pads 222 and deformed in a width direction of the plurality of second upper pads 221 or the plurality of second lower pads 222. Therefore, even though the plurality of second bumps 225 have the same mass or the same volume as each other before the second chip 220 is bonded to the first package 10 through the plurality of second bumps 225, the plurality of second bumps 225 may be deformed further in the first direction D1 by greater contact areas with the plurality of second upper pads 221 and the plurality of second lower pads 222, and thus, the second chip 220 disposed above the plurality of second lower pads 222, the plurality of second bumps 225, and the plurality of second upper pads 221 may be disposed to be inclined with respect to the second direction D2.

According to some example embodiments, widths of the plurality of third upper pads 231 may vary in the second direction D2. The widths of the plurality of third upper pads 231 may decrease with increasing distance from the second chip 220 in the second direction D2. The widths of the plurality of third upper pads 231 may refer to widths of the plurality of third upper pads 231 at (e.g., in or on) a lower surface of the third chip 230. The plurality of third upper pads 231 may include an innermost third upper pad 231i disposed closest, among the third upper pads 231, to the second chip 220 in the second direction D2, and an outermost third upper pad 231o disposed to be spaced farthest apart, among the third upper pads 231, from the second chip 220 in the second direction D2. A width W231i of the innermost third upper pad 231i may be greater than a width W231o of the outermost third upper pad 231o.

According to some example embodiments, widths of the plurality of third lower pads 232 may vary in the second direction D2. The widths of the plurality of third lower pads 232 may decrease with increasing distance from the second chip 220 in the second direction D2. The widths of the plurality of third lower pads 232 may refer to widths of the plurality of third lower pads 232 at (e.g., in or on) the upper surface 10US of the first package 10. The plurality of third lower pads 232 may include an innermost third lower pad 232i disposed closest, among the third lower pads 232, to the second chip 220 in the second direction D2, and an outermost third lower pad 232o disposed to be spaced farthest apart, among the third lower pads 232, from the second chip 220 in the second direction D2. A width of the innermost third lower pad 232i may be greater than a width of the outermost third lower pad 232o.

According to some example embodiments, since the width W231i of the innermost third upper pad 231i is greater than the width W231o of the outermost third upper pad 231o, a contact area between the innermost third upper pad 231i and the innermost third bump 235i may be greater than a contact area between the outermost third upper pad 231o and the outermost third bump 235o. Since the width of the innermost third lower pad 232i is greater than the width of the outermost third lower pad 232o, a contact area between the innermost third lower pad 232i and the innermost third bump 235i may be greater than a contact area between the outermost third lower pad 232o and the outermost third bump 235o.

According to some example embodiments, even though the plurality of third bumps 235 have the same mass or the same volume as each other, greater contact areas of the plurality of third bumps 235 with the plurality of third upper pads 231 and the plurality of third lower pads 232 may lead to a greater degree to which the plurality of third bumps 235 are deformed when the third chip 230 is bonded to the plurality of third lower pads 232 via the plurality of third bumps 235 and the plurality of third upper pads 231. For example, greater widths of the plurality of third upper pads 231 or the plurality of third lower pads 232 may increase at least some portions of the plurality of third bumps 235, which are inserted into trenches formed by the plurality of third upper pads 231 or the plurality of third lower pads 232. As another example, greater widths of the plurality of third upper pads 231 or the plurality of third lower pads 232 may lead to a greater degree to which the plurality of third bumps 235 are deformed in the first direction D1 based on the plurality of third bumps 235 being bonded to the plurality of third upper pads 231 or the plurality of third lower pads 232 and deformed in a width direction of the plurality of third upper pads 231 or the plurality of third lower pads 232. Therefore, even though the plurality of third bumps 235 have the same mass or the same volume as each other before the third chip 230 is bonded to the first package 10 through the plurality of third bumps 235, the plurality of third bumps 235 may be deformed further in the first direction D1 by greater contact areas with the plurality of third upper pads 231 and the plurality of third lower pads 232, and thus, the third chip 230 disposed above the plurality of third lower pads 232, the plurality of third bumps 235, and the plurality of third upper pads 231 may be disposed to be inclined with respect to the second direction D2.

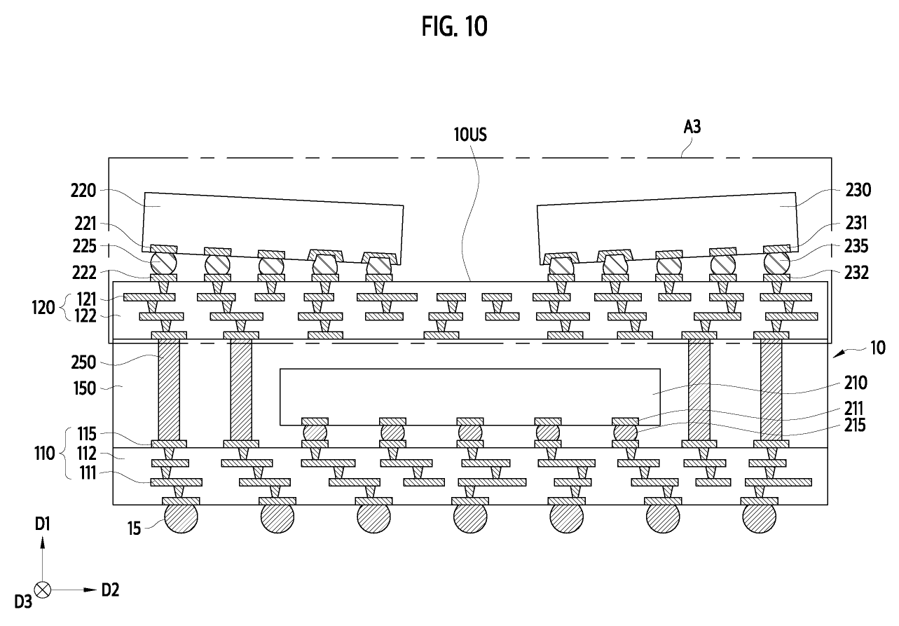

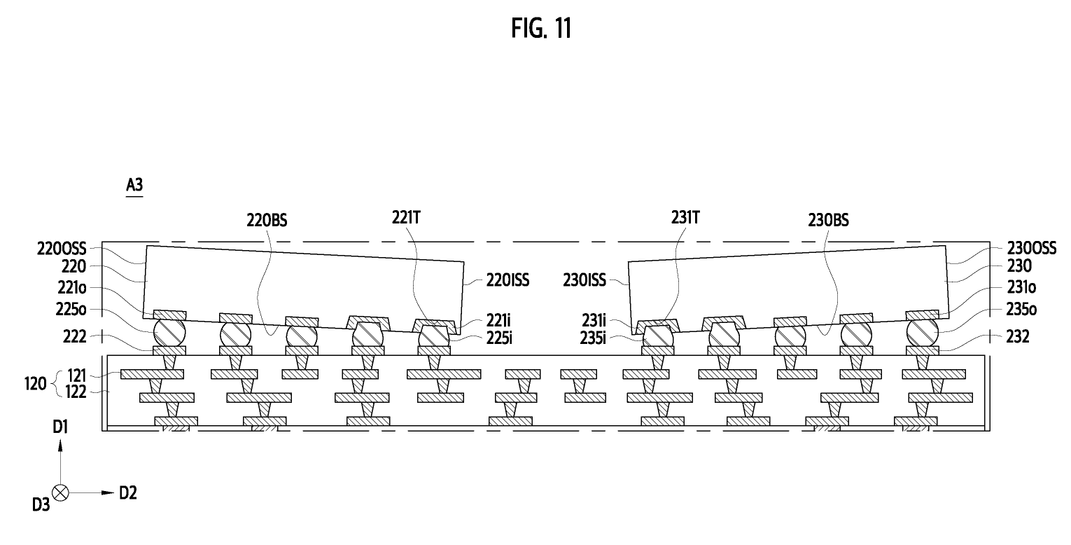

FIG. 10 is another example diagram showing a cross-section taken along the line A-A’ of FIG. 1. FIG. 11 is an example enlarged view showing an area A3 of FIG. 10. To facilitate understanding of the present disclosure, the difference from what is described with reference to FIGS. 1 to 3 is mainly described.

Referring to FIGS. 10 and 11, the innermost second upper pad 221i may be disposed to be inserted to a greater depth in the lower surface 220BS of the second chip 220 than the outermost second upper pad 221o. For example, with respect to the lower surface 220BS of the second chip 220, an upper surface of the innermost second upper pad 221i may be disposed higher than an upper surface of the outermost second upper pad 221o. The innermost second upper pad 221i may be disposed within a second upper trench 221T. The second upper trench 221T may be formed in the lower surface 220BS of the second chip 220. In addition to the innermost second upper pad 221i, at least one or more second upper pads 221 adjacent to the innermost second upper pad 221i in the second direction D2 may be disposed at a greater depth in the lower surface 220BS of the second chip 220 than the outermost second upper pad 221o.

According to some example embodiments, the innermost second upper pad 221i disposed within the second upper trench 221T may form a trench. At least a portion of the innermost second bump 225i may be inserted into the trench formed by the innermost second upper pad 221i. Therefore, even though the plurality of second bumps 225 have the same mass or the same volume as each other, the innermost second bump 225i may be inserted into the trench formed by the innermost second upper pad 221i, and thus, the innermost second bump 225i may be deformed further in the first direction D1 than the outermost second bump 225o. Compared to one side of the second chip 220 where the outermost second upper pad 221o and the outermost second bump 225o are disposed, the other side of the second chip 220 where the innermost second upper pad 221i and the innermost second bump 225i are disposed may be bonded closer to the first package 10 in the first direction D1. Therefore, since the other side of the second chip 220 where the innermost second upper pad 221i and the innermost second bump 225i are disposed is bonded closer to the first package 10 in the first direction D1, the second chip 220 may be disposed to be inclined with respect to the first package 10.

According to some example embodiments, with respect to the lower surface 220BS of the second chip 220, the upper surface of the outermost second upper pad 221o may be disposed lower than the upper surface of the innermost second upper pad 221i. FIGS. 10 and 11 illustrate that no trench is formed by the outermost second upper pad 221o unlike the innermost second upper pad 221i, but example embodiments are not limited thereto. For example, a trench may be formed by the outermost second upper pad 221o, and the trench formed by the outermost second upper pad 221o may be smaller than the trench formed by the innermost second upper pad 221i. For example, with respect to the lower surface 220BS of the second chip 220, a depth of the trench formed by the outermost second upper pad 221o may be smaller than a depth of the trench formed by the innermost second upper pad 221i. Even though at least a portion of the outermost second bump 225o is inserted into the trench formed by the outermost second upper pad 221o, the trench formed by the outermost second upper pad 221o may be smaller than the trench formed by the innermost second upper pad 221i, and thus, a volume of the innermost second bump 225i inserted into the trench formed by the innermost second upper pad 221i may be greater than a volume of the outermost second bump 225o inserted into the trench formed by the outermost second upper pad 221o.

According to some example embodiments, the innermost third upper pad 231i may be disposed to be inserted to a greater depth in the lower surface 230BS of the third chip 230 than the outermost third upper pad 231o. For example, with respect to the lower surface 230BS of the third chip 230, an upper surface of the innermost third upper pad 231i may be disposed higher than an upper surface of the outermost third upper pad 231o. The innermost third upper pad 231i may be disposed within a third upper trench 231T. The third upper trench 231T may be formed in the lower surface 230BS of the third chip 230. In addition to the innermost third upper pad 231i, at least one or more third upper pads 231 adjacent to the innermost third upper pad 231i in the second direction D2 may be disposed at a greater depth in the lower surface 230BS of the third chip 230 than the outermost third upper pad 231o.

According to some example embodiments, the innermost third upper pad 231i disposed within the third upper trench 231T may form a trench. At least a portion of the innermost third bump 235i may be inserted into the trench formed by the innermost third upper pad 231i. Therefore, even though the plurality of third bumps 235 have the same mass or the same volume as each other, the innermost third bump 235i may be inserted into the trench formed by the innermost third upper pad 231i, and thus, the innermost third bump 235i may be deformed further in the first direction D1 than the outermost third bump 235o. Compared to the other side of the third chip 230 where the outermost third upper pad 231o and the outermost third bump 235o are disposed, one side of the third chip 230 where the innermost third upper pad 231i and the innermost third bump 235i are disposed may be bonded closer to the first package 10 in the first direction D1. Therefore, since the one side of the third chip 230 where the innermost third upper pad 231i and the innermost third bump 235i are disposed is bonded closer to the first package 10 in the first direction D1, the third chip 230 may be disposed to be inclined with respect to the first package 10.

According to some example embodiments, with respect to the lower surface 230BS of the third chip 230, the upper surface of the outermost third upper pad 231o may be disposed lower than the upper surface of the innermost third upper pad 231i. FIGS. 10 and 11 illustrate that no trench is formed by the outermost third upper pad 231o unlike the innermost third upper pad 231i, but example embodiments are not limited thereto. For example, a trench may be formed by the outermost third upper pad 231o, and the trench formed by the outermost third upper pad 231o may be smaller than the trench formed by the innermost third upper pad 231i. For example, with respect to the lower surface 230BS of the third chip 230, a depth of the trench formed by the outermost third upper pad 231o may be smaller than a depth of the trench formed by the innermost third upper pad 231i. Even though at least a portion of the outermost third bump 235o is inserted into the trench formed by the outermost third upper pad 231o, the trench formed by the outermost third upper pad 231o may be smaller than the trench formed by the innermost third upper pad 231i, and thus, a volume of the innermost third bump 235i inserted into the trench formed by the innermost third upper pad 231i may be greater than a volume of the outermost third bump 235o inserted into the trench formed by the outermost third upper pad 231o.

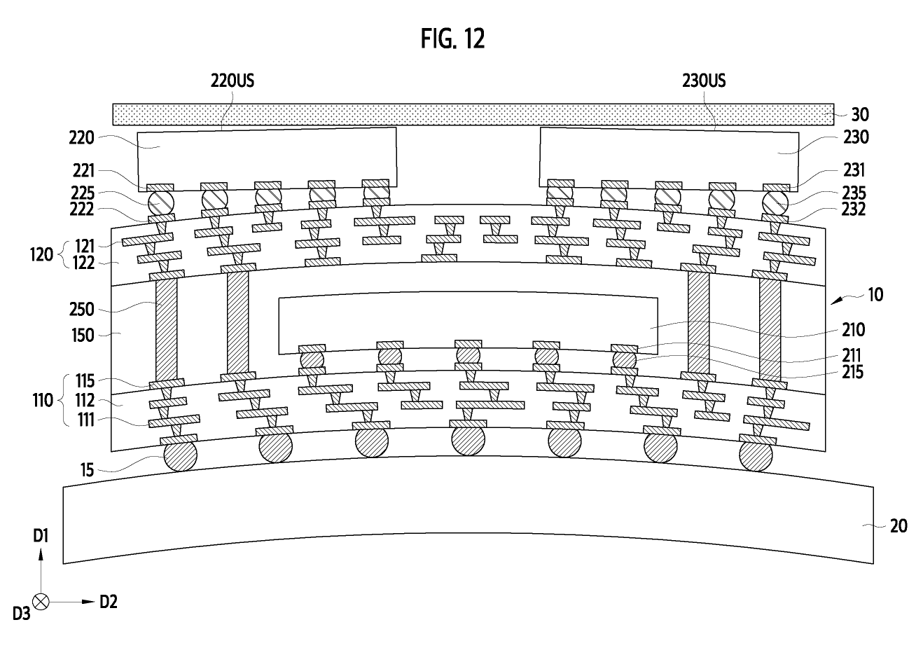

FIG. 12 is an example diagram for illustrating a semiconductor package according to some other example embodiments. To facilitate understanding of the present disclosure, the difference from what is described with reference to FIGS. 1 to 3 is mainly described.

Referring to FIG. 12, the first package 10 provided with the second chip 220 and the third chip 230 may be mounted on an external package substrate 20. The external package substrate 20 may be a wiring structure for a package. For example, the external package substrate 20 may be a PCB, a ceramic substrate, or an interposer. As another example, the external package substrate 20 may be a wiring structure for a WLP fabricated at a wafer level. As another example, the external package substrate 20 may be a front redistribution layer (FRDL) of a fan-out package.

According to some example embodiments, a heat transfer layer 30 may be disposed on the second chip 220 and the third chip 230. The heat transfer layer 30 may cover the upper surface 220US of the second chip 220 and the upper surface 230US of the third chip 230. The heat transfer layer 30 may include, for example, a thermal interface material (TIM) including a polymer, a resin, or epoxy and a filler.

According to some example embodiments, when the external package substrate 20, the first package 10, and the second chip 220 and the third chip 230 are mounted in the first direction D1, warpage may occur due to the difference in the coefficients of thermal expansion of each element. For example, the external package substrate 20 and the first package 10 may be warped such that both ends of the external package substrate 20 and the first package 10 in the second direction D2 are disposed lower than central portions thereof in the second direction D2. When the external package substrate 20 and the first package 10 are warped, upper surfaces of the second chip 220 and the third chip 230 mounted on the first package 10 may also be warped. If the upper surfaces of the second chip 220 and the third chip 230 are warped, the heat transfer layer 30 may not be in stable contact with the second chip 220 and the third chip 230 in a comparative embodiment.

According to some example embodiments, the second chip 220 and the third chip 230 may be mounted on the first package 10 such that the second chip 220 and the third chip 230 are closer to the upper surface 10US of FIG. 2 of the first package 10 with decreasing distance to the central portion of the first package 10 in the second direction D2 and the second chip 220 and the third chip 230 are farther from the upper surface 10US of FIG. 2 of the first package 10 with decreasing distance to both ends of the first package 10 in the second direction D2. Therefore, even though the external package substrate 20 and the first package 10 are warped such that both ends of the external package substrate 20 and the first package 10 in the second direction D2 are disposed lower than the central portions thereof in the second direction D2, the upper surface 220US of the second chip 220 and the upper surface 230US of the third chip 230 may be in stable contact with the heat transfer layer 30. According to example embodiments, it is possible to increase heat dissipation performance despite warpage in a semiconductor package.

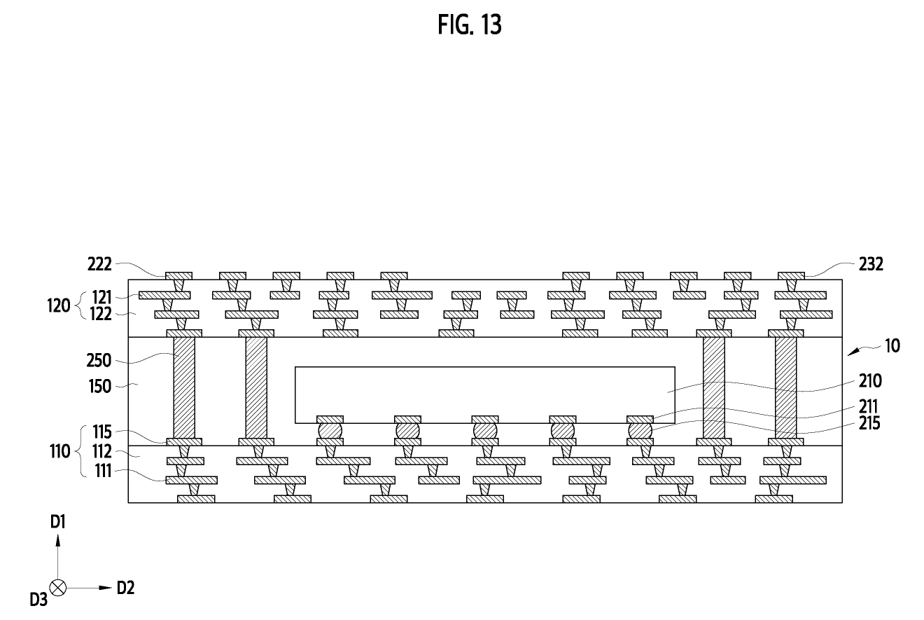

FIGS. 13 to 17 are example diagrams of intermediate stages for illustrating a method of fabricating a semiconductor package according to some example embodiments. To facilitate understanding of the present disclosure, the difference from what is described with reference to FIGS. 1 to 12 is mainly described.

Referring to FIG. 13, the first redistribution structure 110, the first chip 210, and the second redistribution structure 120 may be formed. The plurality of second lower pads 222 and the plurality of third lower pads 232 may be formed on the second redistribution structure 120. FIG. 13 illustrates that widths of the plurality of second lower pads 222 and the plurality of third lower pads 232 in the second direction D2 are uniform, but example embodiments are not limited thereto. For example, when the semiconductor package described with reference to FIGS. 8 and 9 is fabricated, the plurality of second lower pads 222 may be formed such that the widths of the plurality of second lower pads 222 in the second direction D2 increase with decreasing distance to the plurality of third lower pads 232 in the second direction D2, and the plurality of third lower pads 232 may be formed such that the widths of the plurality of third lower pads 232 in the second direction D2 decrease with increasing distance from the plurality of second lower pads 222 in the second direction D2.

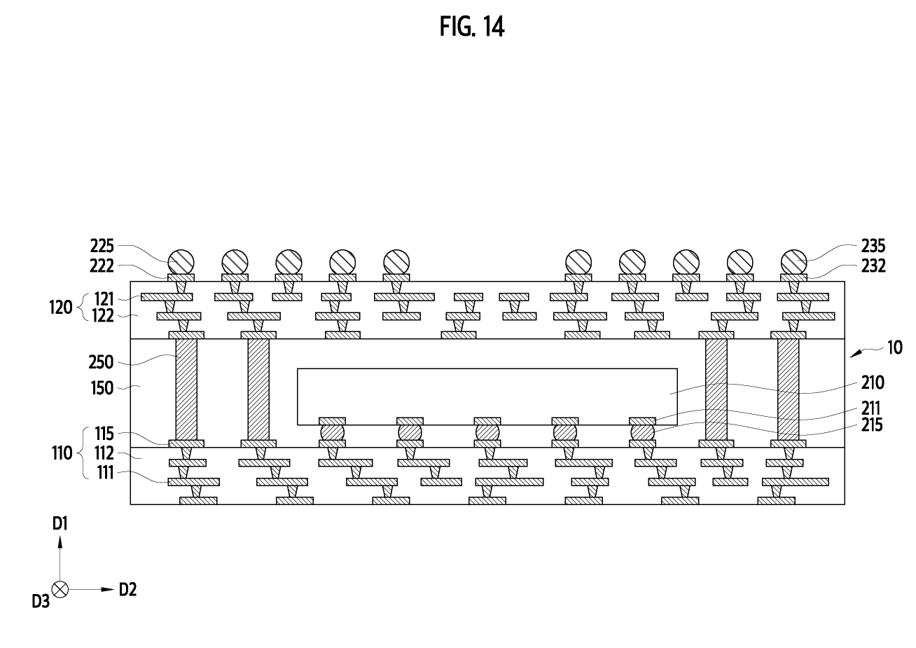

Referring to FIG. 14, the plurality of second bumps 225 may be formed on the plurality of second lower pads 222, and the plurality of third bumps 235 may be formed on the plurality of third lower pads 232. FIG. 14 illustrates that all of the plurality of second bumps 225 and the plurality of third bumps 235 have only a single layer, but example embodiments are not limited thereto. For example, when the semiconductor package described with reference to FIG. 5 is fabricated, the outermost second bump 225o of FIG. 5 or one or more second bumps 225 adjacent to the outermost second bump 225o of FIG. 5 in the second direction D2 may be formed to include multiple layers, and the outermost third bump 235o of FIG. 5 or one or more third bumps 235 adjacent to the outermost third bump 235o of FIG. 5 in the second direction D2 may be formed to include multiple layers.

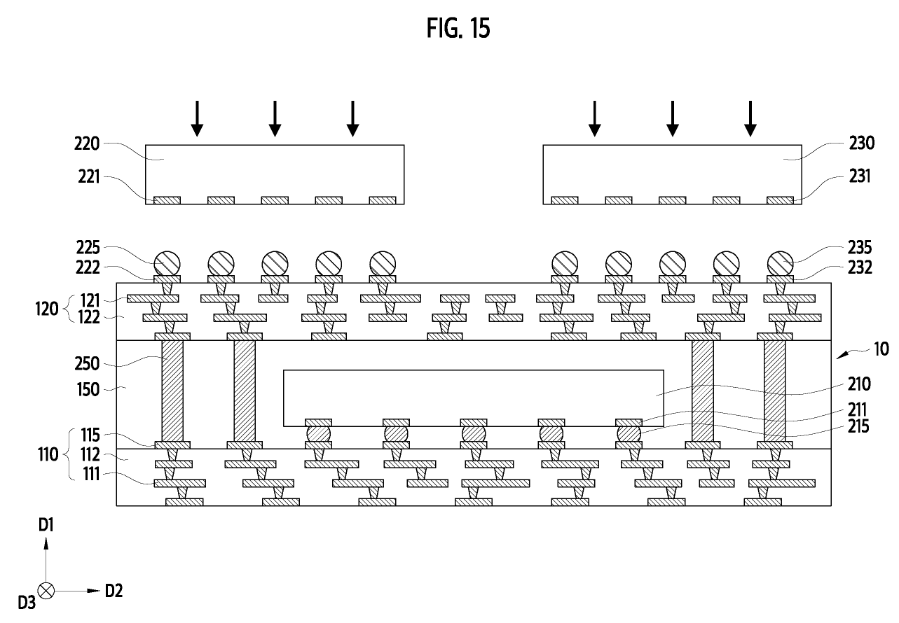

Referring to FIG. 15, pressure may be applied to the second chip 220 such that the plurality of second upper pads 221 are disposed on the plurality of second bumps 225, which are on the plurality of second lower pads 222. Pressure may be applied to the third chip 230 such that the plurality of third upper pads 231 are disposed on the plurality of third bumps 235, which are on the plurality of third lower pads 232. FIG. 15 illustrates that all of the plurality of second upper pads 221 are disposed at the same depth with respect to the lower surface 220BS of FIG. 3 of the second chip 220 and all of the plurality of third upper pads 231 are disposed at the same depth with respect to the lower surface 230BS of FIG. 3 of the third chip 230, but example embodiments are not limited thereto. For example, when the semiconductor package described with reference to FIGS. 10 and 11 is fabricated, the second upper trench 221T of FIG. 11 may be formed in the lower surface 220BS of FIG. 11 of the second chip 220, and the innermost second upper pad 221i of FIG. 11 may be formed within the second upper trench 221T of FIG. 11. Similarly, the third upper trench 231T of FIG. 11 may be formed in the lower surface 230BS of FIG. 11 of the third chip 230, and the innermost third upper pad 231i of FIG. 11 may be formed within the third upper trench 231T of FIG. 11.

FIGS. 14 and 15 illustrate that the plurality of second bumps 225 are formed on the plurality of second lower pads 222, the plurality of third bumps 235 are formed on the plurality of third lower pads 232, the second chip 220 is disposed on and connected to the plurality of second bumps 225, and the third chip 230 is disposed on and connected to the plurality of third bumps 235, but example embodiments are not limited thereto.

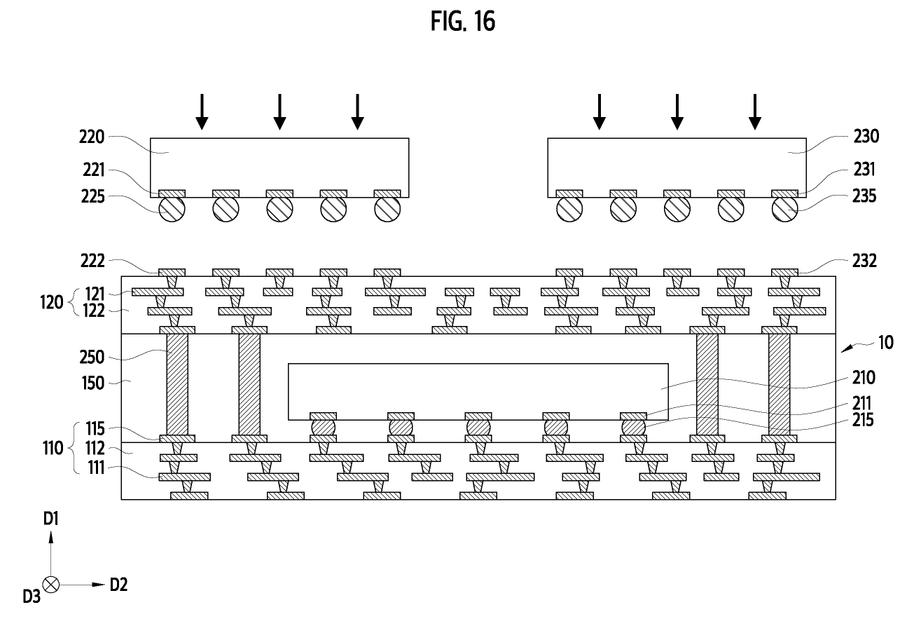

Referring to FIG. 16, the plurality of second bumps 225 may be formed below the plurality of second upper pads 221 of the second chip 220, and the plurality of third bumps 235 may be formed below the plurality of third upper pads 231 of the third chip 230. Pressure may be applied to the second chip 220 where the plurality of second bumps 225 are formed above the first package 10 such that the plurality of second bumps 225 are disposed on and connected to the plurality of second lower pads 222. Pressure may be applied to the third chip 230 where the plurality of third bumps 235 are formed above the first package 10 such that the plurality of third bumps 235 are disposed on and connected to the plurality of third lower pads 232.

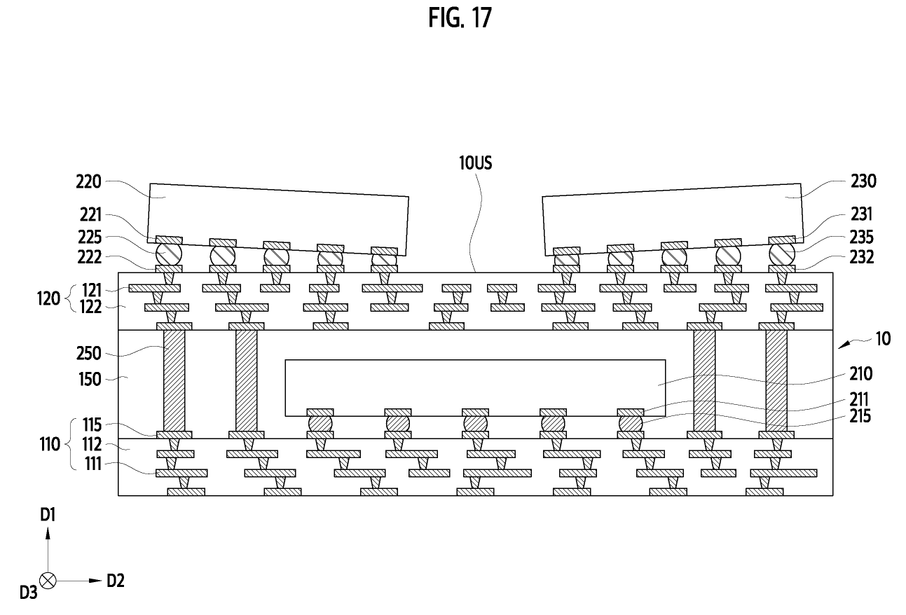

Subsequently, referring to FIG. 17, the second chip 220 may be connected to the second redistribution structure 120 through the plurality of second bumps 225. The second chip 220 may be connected to the plurality of second lower pads 222 through the plurality of second bumps 225. Pressure may be applied to the second chip 220 above the plurality of second lower pads 222, the plurality of second bumps 225, and the plurality of second upper pads 221 such that the second chip 220 is inclined with respect to the upper surface 10US of the first package 10. Specifically, the pressure may be applied to the second chip 220 such that the upper surface 220US of FIG. 3 and the lower surface 220BS of FIG. 3 of the second chip 220 are closer to the upper surface 10US of the first package 10 with decreasing distance to the third chip 230 in the second direction D2.

According to some example embodiments, as the innermost second bump 225i of FIG. 3 among the plurality of second bumps 225 is deformed further in the first direction D1 than the outermost second bump 225o of FIG. 3, the second chip 220 may be formed to be inclined. The innermost second bump 225i of FIG. 3 being deformed further in the first direction D1 than the outermost second bump 225o of FIG. 3 may indicate that a degree of the innermost second bump 225i of FIG. 3 being pressed in the first direction D1 compared to the second bumps 225 before pressing is greater than that of the outermost second bump 225o of FIG. 3.

According to some example embodiments, if the innermost second upper pad 221i of FIG. 11 is formed within the second upper trench 221T of FIG. 11 as shown in FIG. 11, pressure may be applied to the second chip 220 such that at least a portion of the innermost second bump 225i of FIG. 11 is inserted into a trench formed by the innermost second upper pad 221i of FIG. 11.

Similarly, the third chip 230 may be connected to the second redistribution structure 120 through the plurality of third bumps 235 to be spaced apart from the second chip 220 in the second direction D2. The third chip 230 may be connected to the plurality of third lower pads 232 through the plurality of third bumps 235. Pressure may be applied to the third chip 230 above the plurality of third lower pads 232, the plurality of third bumps 235, and the plurality of third upper pads 231 such that the third chip 230 is inclined with respect to the upper surface 10US of the first package 10. Specifically, the pressure may be applied to the third chip 230 such that the upper surface 230US of FIG. 3 and the lower surface 230BS of the FIG. 3 of the third chip 230 are closer to the upper surface 10US of the first package 10 with decreasing distance to the second chip 220, and the upper surface 230US of FIG. 3 and the lower surface 230BS of the FIG. 3 of the third chip 230 are farther from the upper surface 10US of the first package 10 with increasing distance from the second chip 220 in the second direction D2.

According to some example embodiments, as the innermost third bump 235i of FIG. 3 among the plurality of third bumps 235 is deformed further in the first direction D1 than the outermost third bump 235o of FIG. 3, the third chip 230 may be formed to be inclined. The innermost third bump 235i of FIG. 3 being deformed further in the first direction D1 than the outermost third bump 235o of FIG. 3 may indicate that a degree of the innermost third bump 235i of FIG. 3 being pressed in the first direction D1 compared to the third bumps 235 before pressing is greater than that of the outermost third bump 235o of FIG. 3.

According to some example embodiments, if the innermost third upper pad 231i of FIG. 11 is formed within the third upper trench 231T of FIG. 11 as shown in FIG. 11, pressure may be applied to the third chip 230 such that at least a portion of the innermost third bump 235i of FIG. 11 is inserted into a trench formed by the innermost third upper pad 231i of FIG. 11.

Subsequently, referring to FIG. 2, the external connection terminal 15 may be formed below the first redistribution structure 110.

According to some example embodiments, a method of fabricating a semiconductor package may include: connecting, by second bumps, a first package to a second chip above the first package in a first direction intersecting with an upper surface of the first package, wherein the first package includes a first chip; and connecting, by third bumps, a third chip above the first package to the first package, the third chip being spaced apart from the second chip in a second direction intersecting with the first direction, wherein the connecting the first package to the second chip comprises applying pressure to the second chip such that an upper surface of the second chip is inclined with respect to the upper surface of the first package, and wherein the connecting the third chip to the first package comprises applying pressure to the third chip such that an upper surface of the third chip is inclined with respect to the upper surface of the first package.

According to some example embodiments, a sign of a slope of the upper surface of the second chip with respect to the second direction is different from a sign of a slope of the upper surface of the third chip with respect to the second direction.

According to some example embodiments, the applying the pressure to the second chip comprises deforming an innermost second bump closest, among the second bumps, to the third chip in the second direction further in the first direction than an outermost second bump spaced farthest apart, among the second bumps, from the third chip in the second direction.

According to some example embodiments, the applying the pressure to the third chip comprises deforming an innermost third bump closest, among the third bumps, to the second chip in the second direction further in the first direction than an outermost third bump spaced farthest apart, among the third bumps, from the second chip in the second direction.

According to some example embodiments, the applying the pressure to the second chip comprises applying the pressure to the second chip, which is on the second bumps, such that a height, in the first direction, from the upper surface of the first package to the upper surface of the second chip decreases with decreasing distance to the third chip in the second direction.

According to some example embodiments, the applying the pressure to the third chip comprises applying the pressure to the third chip, which is on the third bumps, such that a height, in the first direction, from the upper surface of the first package to the upper surface of the third chip increases with increasing distance from the second chip in the second direction.

According to some example embodiments, an innermost second bump closest, among the second bumps, to the third chip in the second direction includes only a single layer, and an outermost second bump spaced farthest apart, among the second bumps, from the third chip in the second direction includes multiple layers.

According to some example embodiments, the method further comprises forming, on the first package, an underfill at least partially surrounding the second bumps and the third bumps.

According to some example embodiments, the underfill is on at least a portion of a side surface of the second chip and at least a portion of a side surface of the third chip.

According to some example embodiments, the method further comprises forming a heat transfer layer on the second chip and the third chip.

According to some example embodiments, the first chip includes a logic chip, wherein the second chip includes a memory chip, and wherein the third chip includes a heat dissipation structure.

According to some example embodiments, a method of fabricating a semiconductor package may include: forming a first package, the first package including: a first redistribution structure; a first chip above the first redistribution structure; first bumps connecting the first chip and the first redistribution structure; and a second redistribution structure above the first chip in a first direction intersecting with an upper surface of the first chip, the second redistribution structure connected to the first redistribution structure; forming, on an upper surface of the second redistribution structure, second lower pads and third lower pads connected to the second redistribution structure, the third lower pads being spaced apart from the second lower pads in a second direction intersecting with the first direction; connecting, by second bumps on the second lower pads, a second chip to the second lower pads; and connecting, by third bumps on the third lower pads, a third chip to the third lower pads, wherein the connecting the second chip to the second lower pads comprises applying pressure to the second chip, which is above the second lower pads and the second bumps, such that a height, in the first direction, from the upper surface of the second redistribution structure to an upper surface of the second chip decreases with decreasing distance to the third chip in the second direction, and wherein the connecting the third chip to the third lower pads comprises applying pressure to the third chip, which is above the third lower pads and the third bumps, such that a height, in the first direction, from the upper surface of the second redistribution structure to an upper surface of the third chip increases with increasing distance from the second chip in the second direction.

According to some example embodiments, the forming the second lower pads comprises forming the second lower pads such that widths, in the second direction, of the second lower pads increase with decreasing distance to the third lower pads in the second direction.

According to some example embodiments, the forming the third lower pads comprises forming the third lower pads such that widths, in the second direction, of the third lower pads decrease with increasing distance from the second lower pads in the second direction.

According to some example embodiments, a width, in the second direction, of an innermost second lower pad closest, among the second lower pads, to the third lower pads is greater than a width, in the second direction, of an outermost second lower pad spaced farthest apart, among the second lower pads, from the third lower pads in the second direction.

According to some example embodiments, a width, in the second direction, of an innermost third lower pad closest, among the third lower pads, to the second lower pads is greater than a width, in the second direction, of an outermost third lower pad spaced farthest apart, among the third lower pads, from the second lower pads.

According to some example embodiments, the second chip includes: second upper pads on a lower surface of the second chip and connected to the second bumps, and wherein an innermost second upper pad closest, among the second upper pads, to the third chip in the second direction is inserted to a greater depth in the lower surface of the second chip than an outermost second upper pad spaced farthest apart, among the second upper pads, from the third chip in the second direction.

According to some example embodiments, the connecting the second chip to the second lower pads comprises applying pressure to the second chip such that at least a portion of an innermost second bump closest, among the second bumps, to the third chip in the second direction is inserted into a trench formed by the innermost second upper pad.

According to some example embodiments, the first package further includes: a wiring post extending in the first direction and connecting the first redistribution structure and the second redistribution structure; and a molding layer between the first redistribution structure and the second redistribution structure and at least partially surrounding the first chip and the wiring post.

According to some example embodiments, a method of fabricating a semiconductor package may include: connecting, by second bumps, a first package to a second chip above the first package in a first direction intersecting with an upper surface of the first package, wherein the first package includes a first chip; connecting, by third bumps, a third chip above the first package to the first package, the third chip being spaced apart from the second chip in a second direction intersecting with the first direction; mounting the first package, to which the second chip and the third chip are connected, on an external package substrate; and forming a heat transfer layer on the second chip and the third chip, wherein the connecting the second chip to the first package comprises applying pressure to the second chip, which is on the second bumps, such that a height, in the first direction, from the upper surface of the first package to an upper surface of the second chip decreases with decreasing distance to the third chip in the second direction, wherein the connecting the third chip to the first package comprises applying pressure to the third chip, which is on the third bumps, such that a height, in the first direction, from the upper surface of the first package to an upper surface of the third chip increases with increasing distance from the second chip in the second direction, and wherein, by the first package being mounted on the external package substrate, the first package is warped such that both ends of the first package in the second direction are lower than a central portion of the first package between the both ends.

While various non-limiting example embodiments of the present disclosure are described above in detail, the scope of the present disclosure is not limited thereto, and it may be apparent to those of ordinary skill in the art that various modifications and variations may be made without departing from the spirit and scope of the present disclosure. Furthermore, the aforementioned example embodiments may be implemented with some elements removed, and example embodiments may be implemented in combination with each other.

What is claimed is:

1. A semiconductor package comprising:
a first package comprising a first chip;
a second chip above the first package in a first direction intersecting with an upper surface of the first package; and
a third chip above the first package, the third chip spaced apart from the second chip in a second direction intersecting with the first direction,
wherein a height, in the first direction, from the upper surface of the first package to an upper surface of the second chip decreases with decreasing distance to the third chip in the second direction, and
wherein a height, in the first direction, from the upper surface of the first package to an upper surface of the third chip increases with increasing distance from the second chip in the second direction.

2. The semiconductor package of claim 1, further comprising:
second bumps between the second chip and the first package; and
third bumps between the third chip and the first package,
wherein thicknesses, in the first direction, of the second bumps decrease with decreasing distance to the third chip in the second direction, and
wherein thicknesses, in the first direction, of the third bumps increase with increasing distance from the second chip in the second direction.

3. The semiconductor package of claim 2, further comprising:
second upper pads at a lower surface of the second chip, the second upper pads being on the second bumps; and
third upper pads at a lower surface of the third chip, the third upper pads being on the third bumps,
wherein a width, in the second direction, of an innermost second upper pad that is closest, among the second upper pads, to the third chip is greater than a width, in the second direction, of an outermost second upper pad that is farthest apart, among the second upper pads, from the third chip.

4. The semiconductor package of claim 3, wherein a width, in the second direction, of an innermost third upper pad that is closest, among the third upper pads, to the second chip is greater than a width, in the second direction, of an outermost third upper pad that is spaced farthest apart, among the third upper pads, from the second chip.

5. The semiconductor package of claim 2, further comprising:
second lower pads on the first package and below the second bumps; and
third lower pads on the first package and below the third bumps, the third lower pads spaced apart from the second lower pads in the second direction,
wherein contact areas between the second lower pads and the second bumps increase with decreasing distance to the third chip in the second direction, and
wherein contact areas between the third lower pads and the third bumps decrease with increasing distance from the second chip in the second direction.

6. The semiconductor package of claim 2, wherein an outermost second bump that is spaced farthest apart, among the second bumps, from the third chip comprises a material different from a material of an innermost second bump that is closest, among the second bumps, to the third chip.

7. The semiconductor package of claim 6, wherein the outermost second bump comprises multiple layers, and
wherein the innermost second bump comprises only a single layer.

8. The semiconductor package of claim 1, wherein a side surface of the second chip is at a non-perpendicular angle with respect to the upper surface of the first package.

9. The semiconductor package of claim 8, wherein a sign of a slope of the side surface of the second chip with respect to the second direction is different from a sign of a slope of a side surface of the third chip with respect to the second direction.

10. The semiconductor package of claim 1, wherein a height, in the first direction, from the upper surface of the first package to a lower surface of the second chip decreases with decreasing distance to the third chip in the second direction, and
wherein a height, in the first direction, from the upper surface of the first package to a lower surface of the third chip increases with increasing distance from the second chip in the second direction.

11. The semiconductor package of claim 1, wherein a distance between a side surface of the second chip and a side surface of the third chip decreases with increasing distance from the first package in the first direction,
wherein the side surface of the second chip and the side surface of the third chip face each other.

12. The semiconductor package of claim 1, wherein the third chip comprises a heat dissipation structure.

13. The semiconductor package of claim 1, wherein the first chip comprises a logic chip, and the second chip comprises a memory chip.

14. A semiconductor package comprising:
a first package comprising a first chip;
a second chip above the first package in a first direction intersecting with an upper surface of the first package, wherein the second chip is inclined with respect to the upper surface of the first package; and
a third chip above the first package in the first direction and spaced apart from the second chip in a second direction intersecting with the first direction, wherein the third chip is inclined with respect to the upper surface of the first package,
wherein a sign of a slope of an upper surface of the second chip with respect to the second direction is different from a sign of a slope of an upper surface of the third chip with respect to the second direction.

15. The semiconductor package of claim 14, wherein a distance, in the second direction, between the upper surface of the second chip and the upper surface of the third chip increases with increasing distance from the first package in the first direction.

16. The semiconductor package of claim 14, wherein, with respect to the upper surface of the first package,
a height, in the first direction, of an innermost end of the upper surface of the second chip, is different from a height, in the first direction, of an innermost end of the upper surface of the third chip in the first direction, wherein the innermost end of the upper surface of the second chip is closest, among portions of the second chip, to the third chip, and the innermost end of the upper surface of the third chip is closest, among portions of the third chip, to the second chip, and
a height, in the first direction, of an outermost end of the upper surface of the second chip is different from a height of an outermost end of the upper surface of the third chip in the first direction, wherein the outermost end of the upper surface of the second chip is farthest, among the portions of the second chip, from the third chip, and the outermost end of the upper surface of the third chip is farthest, among the portions of the third chip, from the second chip.

17. The semiconductor package of claim 14, wherein a side surface of the second chip is inclined toward the third chip, and
wherein a side surface of the third chip is inclined toward the second chip.

18. The semiconductor package of claim 14, further comprising:
second bumps between the second chip and the first package; and
third bumps between the third chip and the first package,
wherein thicknesses, in the first direction, of the second bumps decrease with decreasing distance to the third chip in the second direction, and
wherein thicknesses, in the first direction, of the third bumps increase with increasing distance from the second chip in the second direction.

19. The semiconductor package of claim 18, further comprising:
an underfill on the first package, the underfill at least partially surrounding the second bumps or the third bumps.

20. A semiconductor package comprising:
a first redistribution structure;
a first chip above the first redistribution structure and connected to the first redistribution structure;
a first bumps connecting the first redistribution structure and the first chip;
a second redistribution structure above the first chip;
a wiring post connecting the first redistribution structure and the second redistribution structure;
a molding layer on the first redistribution structure and at least partially surrounding the first chip and the wiring post;
a second chip above the second redistribution structure in a first direction intersecting with an upper surface of the first chip;
second bumps connecting the second redistribution structure and the second chip;
a third chip above the second redistribution structure and spaced apart from the second chip in a second direction intersecting with the first direction, the third chip comprising a heat dissipation structure; and
third bumps connecting the second redistribution structure and the third chip,
wherein a height, in the first direction, of an innermost end of an upper surface of the second chip is smaller than a height, in the first direction, of an outermost end of the upper surface of the second chip, wherein the innermost end of the upper surface of the second chip is closest, among portions of the second chip, to the third chip in the second direction, and the outermost end of the upper surface of the second chip is spaced farthest apart, among the portions of the second chip, from the third chip in the second direction,
wherein a height, in the first direction, of an innermost end of an upper surface of the third chip is smaller than a height, in the first direction, of an outermost end of the upper surface of the third chip, wherein the innermost end of the upper surface of the third chip is closest, among portions of the third chip, to the second chip in the second direction, and the outermost end of the upper surface of the third chip is spaced farthest apart, among the portions of the third chip, from the second chip in the second direction,
wherein a thickness, in the first direction, of an innermost second bump closest, among the second bumps, to the innermost end of the upper surface of the second chip in the second direction is smaller than a thickness, in the first direction, of an outermost second bump closest, among the second bumps, to the outermost end of the upper surface of the second chip in the second direction, and
wherein a thickness, in the first direction, of an innermost third bump closest, among the third bumps, to the innermost end of the upper surface of the third chip in the second direction is smaller than a thickness, in the first direction, of an outermost third bump closest, among the third bumps, to the outermost end of the upper surface of the third chip in the second direction.
